(19) United States
(12) Patent Application Publication
(10) Pub. No.: US 2026/0165105 A1
(43) Pub. Date: Jun. 11, 2026

(54) SEMICONDUCTOR CHIP AND SEMICONDUCTOR STACK STRUCTURE INCLUDING THE SAME

(71) Applicant: Samsung Electronics Co., Ltd., Suwon-si (KR)

(72) Inventors: Yiyoung Kim, Suwon-si (KR); Wonil Lee, Suwon-si (KR); Raeyoung Kang, Suwon-si (KR); Jihoon Kim, Suwon-si (KR)

(21) Appl. No.: 19/409,080

(22) Filed: Dec. 4, 2025

(30) Foreign Application Priority Data
Dec. 10, 2024 (KR) 10-2024-0183115

(51) Int. Cl. H01L 23/00; H01L 23/48; H01L 25/065

(52) U.S. Cl. CPC H10W 20/20; H10W 90/00; H10W 72/934; H10W 72/936; H10W 72/944; H10W 90/26; H10W 90/297; H10W 90/792

(57) ABSTRACT

A semiconductor chip includes a body having a front surface and a back surface, a back insulating structure on the back surface of the body, the back insulating structure including a back passivation layer, a back etch stop layer and a back bonding insulating layer, sequentially formed on the back surface, and a back pad structure in the back insulating structure on the back surface of the body. The back pad structure includes a back pad pattern including a plurality of first back pad patterns to be spaced apart from each other in a horizontal direction in the back passivation layer, and a second back pad pattern below the plurality of first back pad patterns, and having a width and a thickness greater than a width and a thickness of each of the plurality of first back pad patterns.

### CROSS-REFERENCE TO RELATED APPLICATION

This application is based on and claims priority under 35 U.S.C. § 119 to Korean Patent Application No. 10-2024-0183115, filed on Dec. 10, 2024, in the Korean Intellectual Property Office, the disclosure of which is incorporated by reference herein in its entirety.

### BACKGROUND

This disclosure relates to a semiconductor chip and a semiconductor stack structure including the same, and more particularly to, a semiconductor chip with excellent bonding reliability and a semiconductor stack structure including the same.

Semiconductor chips capable of processing high capacity and high-speed data are required in electronic systems requiring data processing. Accordingly, technology for reliably stacking a plurality of semiconductor chips is needed.

### SUMMARY

This disclosure provides a semiconductor chip with an excellent bonding reliability.

This disclosure provides a semiconductor stack structure including a semiconductor chip with an excellent bonding reliability.

According to some implementations, there is provided a semiconductor chip including a body having a front surface and a back surface, a back insulating structure on the back surface of the body, the back insulating structure including a back passivation layer, a back etch stop layer, and a back bonding insulating layer sequentially disposed on the back surface, and a back pad structure in the back insulating structure on the back surface. The back pad structure includes a plurality of first back pad patterns spaced apart from each other in a horizontal direction in the back passivation layer, and a second back pad pattern below the plurality of first back pad patterns, and having a width and a thickness greater than a width and a thickness of each of the plurality of first back pad patterns.

According to some implementations, there is provided a semiconductor chip including a body having a front surface and a back surface, a through via extending through the front surface and the back surface, a back insulating structure disposed on the back surface of the body and surrounding the through via, the back insulating structure including a back passivation layer, a back etch stop layer, and a back bonding insulating layer sequentially disposed on the back surface, and a back pad structure in the back insulating structure on the back surface of the body.

The back pad structure includes a back pad pattern including a plurality of first back pad patterns spaced apart from each other in a horizontal direction in the back passivation layer and spaced apart from the through via in the horizontal direction, and a second back pad pattern below the plurality of first back pad patterns and the back passivation layer, and having a width and a thickness greater than a width and a thickness of each of the plurality of first back pad patterns.

According to some implementations, there is provided a semiconductor stack structure including a lower semiconductor chip, and an upper semiconductor chip stacked on and bonded to the lower semiconductor chip. Each of the lower semiconductor chip and the upper semiconductor chip includes a body having a front surface and a back surface, a through via extending through the front surface and the back surface, a back insulating structure on the back surface of the body and surrounding the through via, the back insulating structure including a back passivation layer, a back etch stop layer, and a back bonding insulating layer sequentially disposed on the back surface, and a back pad structure in the back insulating structure.

The back pad structure includes a plurality of first back pad patterns spaced apart from each other in a horizontal direction in the back passivation layer and spaced apart from the through via in the horizontal direction, and a second back pad pattern below each of the plurality of first back pad patterns and the back passivation layer, and having a width and a thickness greater than a width and a thickness of each of the plurality of first back pad patterns.

### BRIEF DESCRIPTION OF THE DRAWINGS

Some implementations will be more clearly understood from the following detailed description taken in conjunction with the accompanying drawings in which:

FIG. 1 is a cross-sectional view illustrating a semiconductor chip according to some implementations;

FIG. 2 is an enlarged view of an EN1 region of FIG. 1;

FIG. 3 is an enlarged view of an EN2 region of FIG. 1;

FIG. 4 is an enlarged view of FIG. 2, according to some implementations;

FIG. 5 is an enlarged view of FIG. 3, according to some implementations;

FIG. 6 is a cross-sectional view illustrating a semiconductor chip according to some implementations;

FIG. 7 is an enlarged view of an EN3 region of FIG. 6;

FIG. 8 is an enlarged view of an EN4 region of FIG. 6;

FIG. 9 is a cross-sectional view illustrating a semiconductor chip according to some implementations;

FIG. 10 is an enlarged view of an EN5 region of FIG. 9;

FIG. 11 is a cross-sectional view illustrating a semiconductor chip according to some implementations;

FIG. 12 is an enlarged view of an EN6 region of FIG. 11;

FIG. 13 is an enlarged view of an EN7 region of FIG. 11;

FIG. 14 is an enlarged view of FIG. 12, according to some implementations;

FIG. 15 is an enlarged view of FIG. 13, according to some implementations;

FIGS. 16 to 19 are cross-sectional views illustrating semiconductor stack structures according to some implementations;

FIGS. 20 to 23 are cross-sectional views illustrating semiconductor stack structures according to some implementations;

FIG. 24 is a cross-sectional view for explaining a memory device including a semiconductor stack structure according to some implementations;

FIGS. 25 to 34 are cross-sectional views illustrating a method of manufacturing a semiconductor chip according to some implementations; and

FIG. 35 is a diagram illustrating a semiconductor package including a semiconductor stack structure according to some implementations.

### DETAILED DESCRIPTION

Hereinafter, some implementations will be described in detail with reference to the accompanying drawings. The same reference numerals are used for the same components in the drawings, and redundant descriptions thereof are omitted.

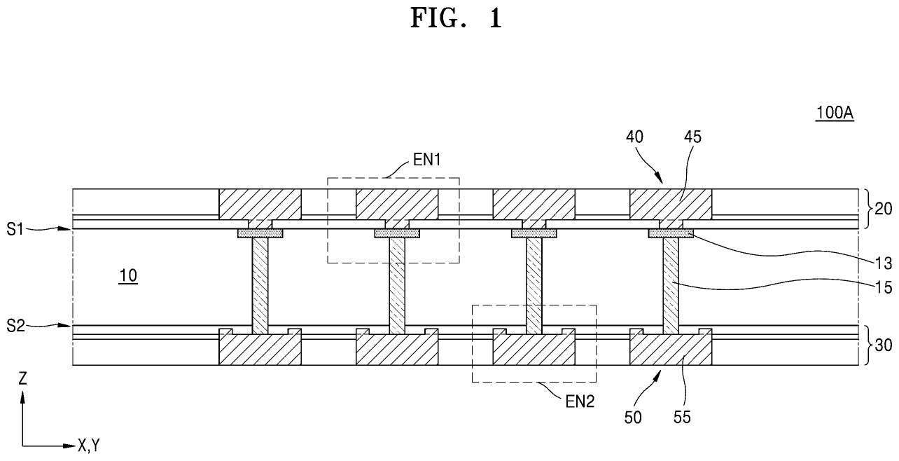

FIG. 1 is a cross-sectional view illustrating a semiconductor chip 100A according to some implementations.

Specifically, the semiconductor chip 100A may include a body 10 having a front surface S1 and a back surface S2, a front insulating structure 20 and a front pad structure 40 disposed on the front surface S1 of the body 10. The semiconductor chip 100A shown in FIG. 1 may be a cross-sectional view at room temperature (25° C.).

The semiconductor chip 100A may include a back insulating structure 30 and a back pad structure 50 disposed on the back surface S2 of the body 10. The semiconductor chip 100A may include an upper metal pattern 13 and a through via 15 formed on and in the body 10. In some implementations, the through via 15 may not be formed.

The body 10 may include a semiconductor substrate such as a silicon wafer, transistors formed on the semiconductor substrate, and circuit structures such as metal wirings. In some implementations, the body 10 may include ceramics, glass, or a printed circuit board (PCB).

The front surface S1 of the body 10 may be an active surface, for example, a surface of an insulating layer covering a circuit structure formed on an upper surface of a semiconductor substrate. The back surface S2 of the body 10 may be a lower surface of a silicon wafer on which no circuit structure is formed.

The front insulating structure 20 may be formed on the front surface S1 of the body 10 to surround side surfaces of the front pad structure 40. The back insulating structure 30 may be formed on the back surface S2 of the body 10 to surround side surfaces of the back pad structure 50.

The upper metal pattern 13 may be disposed in the body 10 to electrically connect the front pad structure 40 to electrical circuits in the body 10. The upper metal pattern 13 may be the uppermost metal layer of a semiconductor circuit.

The upper metal pattern 13 may be disposed adjacent to the front surface S1 of the body 10. The upper metal pattern 13 may include a metal such as aluminum (Al) or tungsten (W). A lower surface of the upper metal pattern 13 may be in contact with an upper end of the through via 15.

The through via 15 may vertically penetrate the body 10 to electrically connect the upper metal pattern 13 to the back pad structure 50. The through via 15 may include a metal layer, for example, copper (Cu).

In some implementations, an insulating via liner (not shown) surrounding a side surface of the through via 15 may be further formed. The insulating via liner may electrically insulate the through via 15 from the body 10. For example, the insulating via liner may include a silicon oxide or silicon nitride-based insulating material.

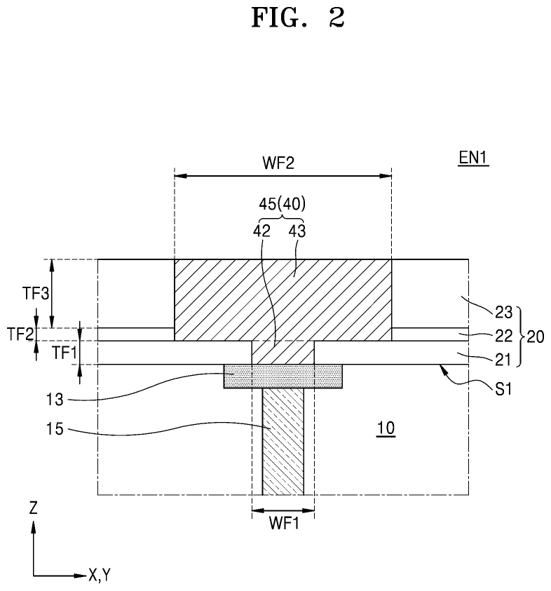

FIG. 2 is an enlarged view of an EN1 region of FIG. 1.

Specifically, as shown in the enlarged view EN1 of FIG. 2, the front pad structure 40 of the semiconductor chip 100A may include a front pad pattern 45 having a first front pad pattern 42 and a second front pad pattern 43. The front pad structure 40 of the semiconductor chip 100A shown in FIG. 2 may have a structure at room temperature (25° C.).

The front insulating structure 20 of the semiconductor chip 100A may include a front passivation layer 21, a front etch stop layer 22, and a front bonding insulating layer 23. The front passivation layer 21 may be formed to be flat on the front surface S1 of the body 10. The front passivation layer 21 may be formed to have a certain thickness TF1.

The front passivation layer 21 may expose a part of an upper surface of the upper metal pattern 13. The front passivation layer 21 may include a silicon oxide-based inorganic insulating layer or a polyimide-based polymer organic insulating layer.

The front etch stop layer 22 may be formed on the front passivation layer 21. The front etch stop layer 22 may be formed to have a certain thickness TF2. The thickness TF2 of the front etch stop layer 22 may be less than the thickness TF1 of the front passivation layer 21. The front etch stop layer 22 may include an insulating material layer such as silicon nitride.

The front bonding insulating layer 23 may be formed on the front etch stop layer 22. The front bonding insulating layer 23 may include an insulating material layer such as silicon oxide. The front bonding insulating layer 23 may be formed to have a certain thickness TF3.

The thickness TF3 of the front bonding insulating layer 23 may be greater than the thickness TF1 of the front passivation layer 21 and the thickness TF2 of the front etch stop layer 22. The thickness TF1 of the front passivation layer 21, the thickness TF2 of the front etch stop layer 22, and the thickness TF3 of the front bonding insulating layer 23 may be several thousands of Å.

The front pad pattern 45 may be formed in the front insulating structure 20. The front pad pattern 45 may be formed on the upper metal pattern 13 and the front passivation layer 21. The first front pad pattern 42 may be electrically connected to the upper metal pattern 13. The first front pad pattern 42 may correspond to a landing portion for being electrically connected to the upper metal pattern 13.

The first front pad pattern 42 may have a certain width WF1. The second front pad pattern 43 may have a certain width WF2 greater than the width WF1 of the first front pad pattern 42. In some implementations, the width WF1 of the first front pad pattern 42 and the width WF2 of the second front pad pattern 43 may be several μm. In some implementations, the width WF2 of the second front pad pattern 43 may be 7 μm to 8 μm. The first front pad pattern 42 and the second front pad pattern 43 may include the same metal, for example, copper.

An upper surface of the front pad structure 40 and an upper surface of the front insulating structure 20 may be the same plane. An upper surface of the second front pad pattern 43 and an upper surface of the front bonding insulating layer 23 may be the same plane. The upper surface of the second front pad pattern 43 may be a flat surface. The first front pad pattern 42 and the second front pad pattern 43 may be formed in an integrated structure. The first front pad pattern 42 and the second front pad pattern 43 may not have a physical interface.

In the front pad structure 40 of the semiconductor chip 100A, the width WF2 of the second front pad pattern 43 is configured to be greater than the width WF1 of the first front pad pattern 42. Accordingly, the front pad structure 40 of the semiconductor chip 100A has a large surface area, thereby improving a bonding reliability when bonding a lower semiconductor chip and an upper semiconductor chip as described below.

In addition, in the front pad structure 40 of the semiconductor chip 100A, the upper surface of the second front pad pattern 43 is configured to be flat. Accordingly, the front pad structure 40 of the semiconductor chip 100A has a flat surface, thereby improving the bonding reliability when bonding the lower semiconductor chip and the upper semiconductor chip as described below.

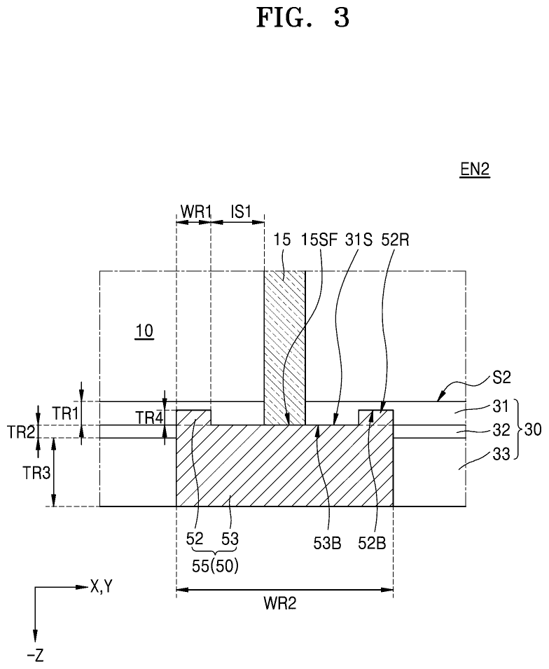

FIG. 3 is an enlarged view of an EN2 region of FIG. 1.

Specifically, as shown in the enlarged view EN2 of FIG. 3, the back insulating structure 30 of the semiconductor chip 100A may include a back passivation layer 31, a back etch stop layer 32, and a back bonding insulating layer 33. The back pad structure 50 of the semiconductor chip 100A may include a back pad pattern 55 including a first back pad pattern 52 and a second back pad pattern 53. The back pad structure 50 of the semiconductor chip 100A shown in FIG. 3 may have a structure at room temperature (25° C.).

The back passivation layer 31 may be formed flat on the back surface S2 of the body 10 and may expose a lower end of the through via 15. The back passivation layer 31 may include a silicon oxide-based inorganic insulating layer or a polyimide-based polymer organic insulating layer. The back passivation layer 31 may be formed to have a certain thickness TR1. The back passivation layer 31 may surround the through via 15.

The back etch stop layer 32 may be formed on the back passivation layer 31. The back etch stop layer 32 may be formed to have a certain thickness TR2. The thickness TR2 of the back etch stop layer 32 may be less than the thickness TR1 of the back passivation layer 31. The back etch stop layer 32 may include an insulating material layer such as silicon nitride.

The back bonding insulating layer 33 may be formed on the back etch stop layer 32. The back bonding insulating layer 33 may include an insulating material layer such as silicon oxide. The back bonding insulating layer 33 may be formed to have a certain thickness TR3.

The thickness TR3 of the back bonding insulating layer 33 may be greater than the thickness TR1 of the back passivation layer 31 and the thickness TR2 of the back etch stop layer 32. The thickness TR1 of the back passivation layer 31, the thickness TR2 of the back etch stop layer 32, and the thickness TR3 of the back bonding insulating layer 33 may be several thousands of Å.

The back pad pattern 55 may be formed in the back insulating structure 30. A plurality of first back pad patterns 52 may be provided in the back passivation layer 31 to be spaced apart from each other in a horizontal direction (X direction or Y direction).

The first back pad pattern 52 may be symmetrically disposed in the horizontal direction with respect to the through via 15. The first back pad pattern 52 may be spaced apart from one side wall of the through via 15 by an isolation distance IS1 in the horizontal direction (X direction or Y direction).

In some implementations, the isolation distance IS1 may be several μm, such as 2 μm to 3 μm. The first back pad pattern 52 may be located in a recess hole 52R recessed from a surface 31S of the back passivation layer 31.

An upper portion (or upper surface) 52B of the first back pad pattern 52 may be formed as a stepped structure on an upper portion (or upper surface) 53B of the second back pad pattern 53. The upper portion (or upper surface) 52B of the first back pad pattern 52 may not have the same plane as the upper portion (or upper surface) 53B of the second back pad pattern 53. An upper surface 52B of each of the plurality of first back pad patterns 52 may be disposed higher than an upper surface of the second back pad pattern 53.

The upper portion (or upper surface) 53B of the second back pad pattern 53 and a lower portion (or lower surface) 15SF of the through via 15 may be located on the same plane. The upper portion (or upper surface) 52B of the first back pad pattern 52 is spaced apart from the back surface S2 of the body 10 in a vertical direction. An upper surface 52B of each of the plurality of first back pad patterns 52 may be spaced apart from the back surface S2 of the body 10 in a vertical direction.

The upper portion (or upper surface) 52B of the first back pad pattern 52 is not in contact with the back surface S2 of the body 10. The first back pad pattern 52 may have a certain width WR1. The width WR1 of the first back pad pattern 52 may be less than or equal to 1 μm.

The first back pad pattern 52 may have a certain thickness TR4. The thickness TR4 of the first back pad pattern 52 may be less than the thickness TR1 of the back passivation layer 31. In some implementations, the thickness TR4 of the first back pad pattern 52 may be 1000 Å to 2000 Å.

The second back pad pattern 53 is formed below the first back pad pattern 52 and the back passivation layer 31, and may have a width WR2 and a thickness (TR2+TR3) greater than those of the first back pad pattern 52. The back pad pattern 55 may be formed below the through via 15. The second back pad pattern 53 may be electrically connected to the through via 15. The through via 15 may contact an upper surface 53B of the second back pad pattern 53. An upper surface 52B of each of the plurality of first back pad patterns may be disposed higher than a lower surface 15SF of the through via 15. In some implementations, a width of the through via 15 may be several μm, for example, 3 μm to 5 μm.

The first back pad pattern 52 may correspond to a pattern for adjusting the expansion of the back pad pattern 55 when a plurality of semiconductor chips 100A are bonded at a high temperature. The first back pad pattern 52 may have a certain width WR1.

The second back pad pattern 53 may have a width WR2 greater than the width WR1 of the first back pad pattern 52. The lower surface of the second back pad pattern 53 may be a flat surface. In some implementations, the width WR2 of the second back pad pattern 53 may be several μm. In some implementations, the width WR2 of the second back pad pattern 53 may be 7 μm to 8 μm.

The first back pad pattern 52 and the second back pad pattern 53 may include the same material, for example, metal. The first back pad pattern 52 and the second back pad pattern 53 may include copper. The first back pad pattern 52 and the second back pad pattern 53 may be formed in an integrated structure. The first back pad pattern 52 and the second back pad pattern 53 may not have a physical interface.

In the back pad structure 50 of the semiconductor chip 100A, the first back pad pattern 52 is provided. Accordingly, the back pad structure 50 of the semiconductor chip 100A has a large surface area, thereby improving a bonding reliability when bonding a lower semiconductor chip and an upper semiconductor chip as described below.

In other words, the back pad structure 50 of the semiconductor chip 100A may further include the first back pad pattern 52 to increase the volume. Accordingly, the bonding reliability may be improved by increasing the amount of expansion of a back pad structure that expands during high-temperature bonding of the lower semiconductor chip and the upper semiconductor chip as described below.

In the back pad structure 50 of the semiconductor chip 100A, a lower surface of the second back pad pattern 53 is formed to be flat. Accordingly, the back pad structure 50 of the semiconductor chip 100A has a flat surface, thereby improving the bonding reliability when bonding the lower semiconductor chip and the upper semiconductor chip as described below.

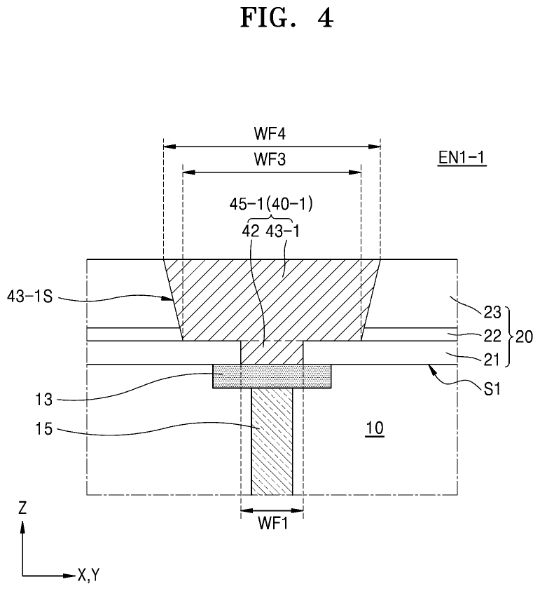

FIG. 4 is an enlarged view EN1-1 of FIG. 2 according to some implementations.

Specifically, the enlarged view EN1-1 of FIG. 4 may be almost the same as the enlarged view EN1 of FIG. 2, except that a structure of a front pad pattern 45-1 constituting a front pad structure 40-1 is different from a structure of the front pad structure 40 of FIG. 2.

In other words, the enlarged view EN1-1 of FIG. 4 may be substantially the same as the enlarged view EN1 of FIG. 2, except that a structure of a second front pad pattern 43-1 constituting the front pad structure 40-1 is different. In FIG. 4, reference numerals identical to or similar to those of FIG. 2 indicate the same or similar members. In FIG. 4, descriptions given with reference to FIG. 2 are briefly explained or omitted.

The front pad structure 40-1 may include the front pad pattern 45-1 including a first front pad pattern 42 and the second front pad pattern 43-1. A lower portion of the second front pad pattern 43-1 may have a certain width WF3. An upper portion of the second front pad pattern 43-1 may have a certain width WF4.

The width WF4 of the upper portion of the second front pad pattern 43-1 may be greater than the width WF3 of the lower portion thereof. The width WF3 of the lower portion of the second front pad pattern 43-1 and the width WF4 of the upper portion of the second front pad pattern 43-1 may be several μm. Accordingly, one side surface 43-1S of the second front pad pattern 43-1 may be an inclined surface with a slope increasing upward.

In the front pad structure 40-1 of the semiconductor chip 100A, the width WF4 of the upper portion of the second front pad pattern 43-1 is configured to be greater than the width WF3 of the lower portion thereof. Accordingly, the front pad structure 40-1 of the semiconductor chip 100A has a large surface area, thereby improving a bonding reliability when bonding a lower semiconductor chip and an upper semiconductor chip as described below.

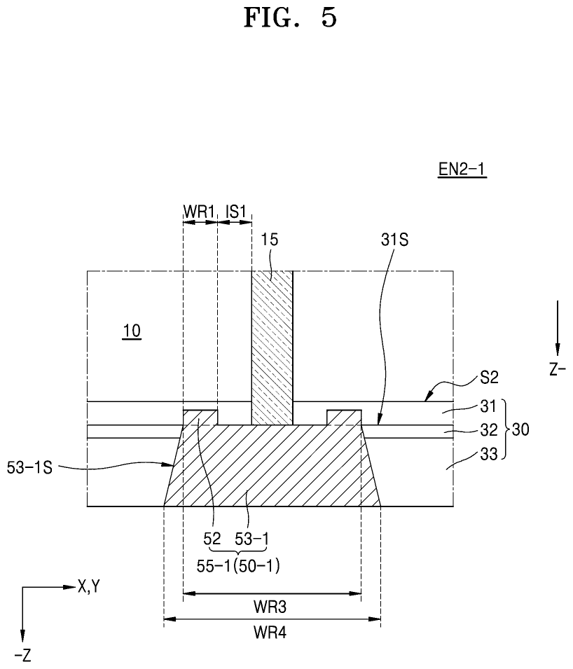

FIG. 5 is an enlarged view EN2-1 of FIG. 3 according to some implementations.

Specifically, the enlarged view EN2-1 of FIG. 5 may be almost the same as the enlarged view EN2 of FIG. 3, except that a structure of a back pad pattern 55-1 constituting a back pad structure 50-1 is different.

In other words, the enlarged view EN2-1 of FIG. 5 may be almost the same the enlarged view EN2 of FIG. 3, except that a structure of a second back pad pattern 53-1 constituting the back pad structure 50-1 is different. In FIG. 5, reference numerals identical to or similar to those of FIG. 3 indicate the same or similar members. In FIG. 5, descriptions given with reference to FIG. 3 are briefly explained or omitted.

The back pad structure 50-1 may include the back pad pattern 55-1 including a first back pad pattern 52 and the second back pad pattern 53-1. An upper portion of the second back pad pattern 53-1 may have a certain width WR3. A lower portion of the second back pad pattern 53-1 may have a certain width WR4.

The width WR4 of the lower portion of the second back pad pattern 53-1 may be different from the width WR3 of the upper portion thereof. The width WR4 of the lower portion of the second back pad pattern 53-1 may be greater than the width WR3 of the upper portion thereof. The width WR3 of the upper portion of the second back pad pattern 53-1 and the width WR4 of the lower portion of the second back pad pattern 53-1 may be several μm. Accordingly, one side surface 53-1S of the second back pad pattern 53-1 may be an inclined surface with a slope increasing downward.

In the back pad structure 50-1 of the semiconductor chip 100A, the width WR4 of the lower portion of the second back pad pattern 53-1 is greater than the width WR3 of the upper portion thereof. Accordingly, the back pad structure 50-1 of the semiconductor chip 100A has a large surface area, thereby improving a bonding reliability when bonding a lower semiconductor chip and an upper semiconductor chip as described below.

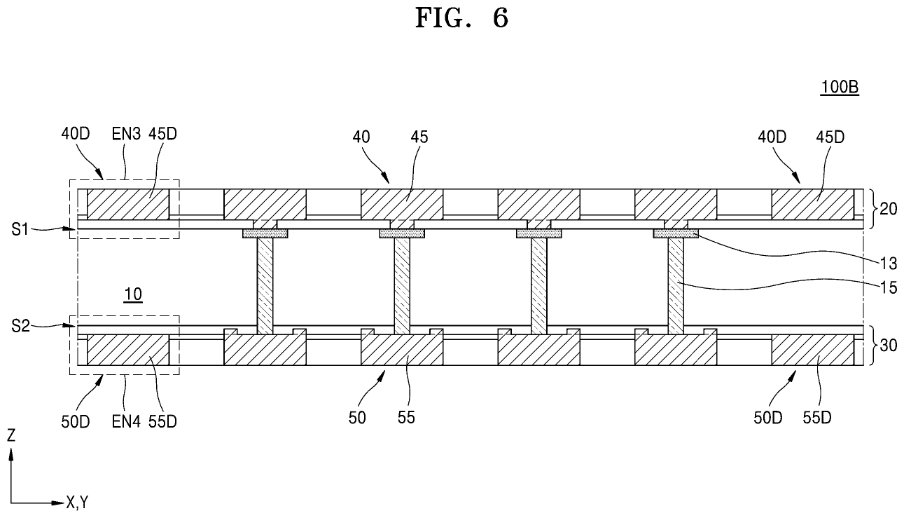

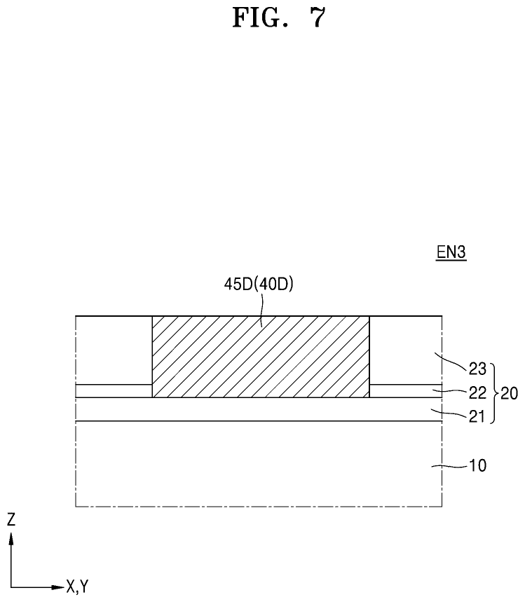

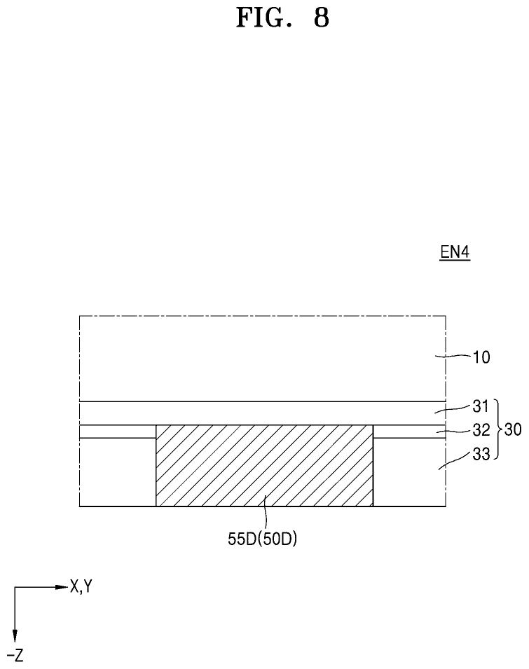

FIG. 6 is a cross-sectional view illustrating a semiconductor chip 100B according to some implementations. FIG. 7 is an enlarged view of an EN3 region of FIG. 6. FIG. 8 is an enlarged view of an EN4 region of FIG. 6.

Specifically, the semiconductor chip 100B may be almost the same as shown in FIGS. 1 to 3, except that the semiconductor chip 100B further includes a dummy front pad structure 40D and a dummy back pad structure 50D.

In FIGS. 6 and 7, reference numerals identical to or similar to those of FIGS. 1 to 3 indicate the same or similar members. In FIGS. 6 and 7, descriptions given with reference to FIGS. 1 to 3 are briefly explained or omitted.

The semiconductor chip 100B may include the body 10 having the front surface S1 and the back surface S2, the front insulating structure 20 disposed on the front surface S1 of the body 10, and front pad structures 40 and 40D. The semiconductor chip 100B may include the back insulating structure 30 and back pad structures 50 and 50D disposed on the back surface S2 of the body 10. The semiconductor chip 100B may include the upper metal pattern 13 and the through via 15 formed in the body 10.

The front insulating structure 20 may include the front passivation layer 21, the front etch stop layer 22, and the front bonding insulating layer 23. The backside insulating structure 30 may include the backside passivation layer 31, the backside etch stop layer 32, and the backside bonding insulating layer 33.

The front pad structures 40 and 40D may include a real front pad structure 40 and a dummy front pad structure 40D. The back pad structures 50 and 50D may include a real back pad structure 50 and a dummy back pad structure 50D.

The real front pad structure 40 may have a real front pad pattern 45. The dummy front pad structure 40D may have a dummy front pad pattern 45D. The dummy front pad pattern 45D may be formed on the front passivation layer 21.

An upper surface of the dummy front pad pattern 45D may be a flat surface. The dummy front pad structure 40D may not be vertically aligned with and may not be electrically connected to the upper metal pattern 13 and the through via 15.

The real back pad structure 50 may have a real back pad pattern 55. The dummy back pad structure 50D may have a dummy back pad pattern 55D. The dummy back pad pattern 55D may be formed on the back passivation layer 31.

A lower surface of the dummy back pad pattern 55D may be a flat surface. The dummy back pad structure 50D may not be vertically aligned with and may not be electrically connected to the upper metal pattern 13 and the through via 15.

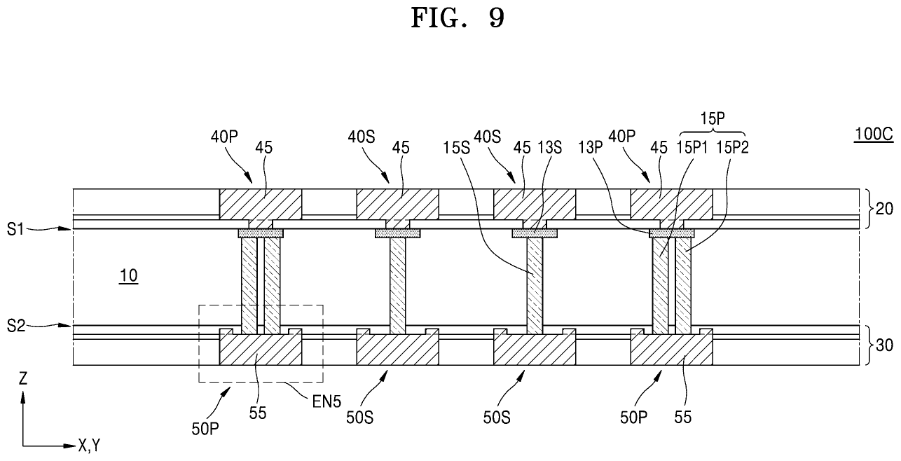

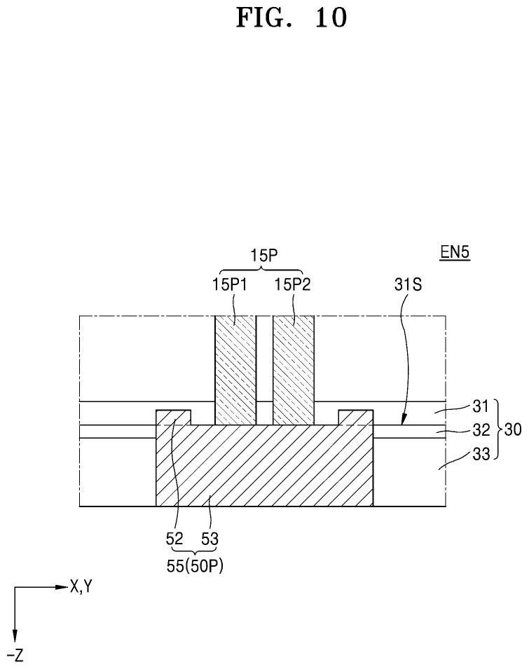

FIG. 9 is a cross-sectional view illustrating a semiconductor chip 100C according to some implementations. FIG. 10 is an enlarged view of an EN5 region of FIG. 9.

Specifically, the semiconductor chip 100C may be almost the same as shown in FIGS. 1 to 3, except that a plurality of through vias 15P1 and 15P2 are included between the front pad pattern 45 and the back pad pattern 55. In FIGS. 9 and 10, reference numerals identical to or similar to those of FIGS. 1 to 3 indicate the same or similar members. In FIGS. 9 and 10, descriptions given with reference to FIGS. 1 to 3 are briefly explained or omitted.

Specifically, the semiconductor chip 100C may include the body 10 having the front surface S1 and the back surface S2, and the front insulating structure 20 and front pad structures 40S and 40P disposed on the front surface S1 of the body 10. The front insulating structure 20 may include the front passivation layer 21, the front etch stop layer 22, and the front bonding insulating layer 23. The front pad structures 40S and 40P may include a front pad pattern 45.

The semiconductor chip 100C may include the back insulating structure 30 and back pad structures 50S and 50P disposed on the back surface S2 of the body 10. The backside insulating structure 30 may include the backside passivation layer 31, the backside etch stop layer 32, and the backside bonding insulating layer 33.

The back pad structures 50S and 50P may include a back pad pattern 55. The back pad pattern 55 may include a first back pad pattern 52 and a second back pad pattern 53. The first back pad pattern 52 may be located within the recess hole 52R (see FIG. 3) recessed from the surface 31S of the back passivation layer 31.

The semiconductor chip 100C may include upper metal patterns 13S and 13P and through vias 15S and 15P formed in the body 10. The front pad structures 40S and 40P may include a signal front pad structure 40S and a power front pad structure 40P. The back pad structures 50S and 50P may include a signal back pad structure 50S and a power back pad structure 50P.

The upper metal patterns 13S and 13P may include a signal upper metal pattern 13S and a power upper metal pattern 13P. The through vias 15S and 15P may include a signal through via 15S and a power through via 15P. The signal front pad structure 40S, the signal back pad structure 50S, the signal upper metal pattern 13S, and the signal through via 15S may transfer a clock signal, a command signal, an address signal, or a data signal.

The power front pad structure 40P, the power back pad structure 50P, the power upper metal pattern 13P, and the power through via 15P may transfer reference voltages Vrefs. In order to transfer stable reference voltages, components for power transmission may have dual or double signal transmission paths.

For example, the power through via 15P may include the plurality of power through vias 15P1 and 15P2. The plurality of power through vias 15P1 and 15P2 may electrically connect the power upper metal pattern 13P to the power back pad structure 50P. The signal through via 15S and the power through vias 15P1 and 15P2 may have the same material, the same length, and the same width or diameter.

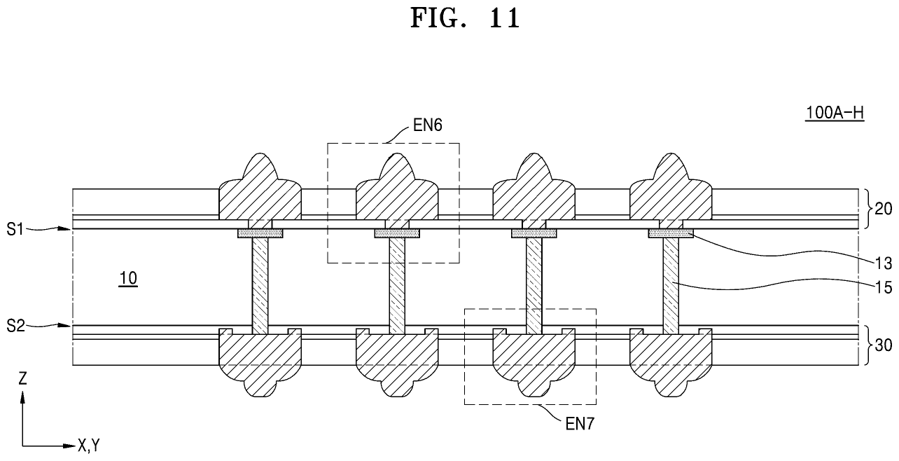

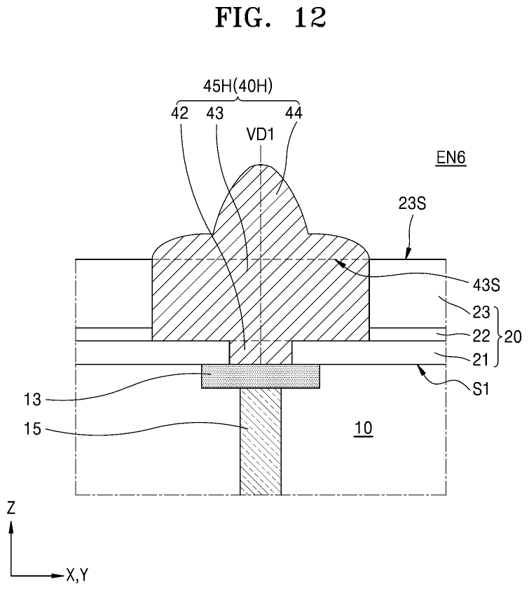

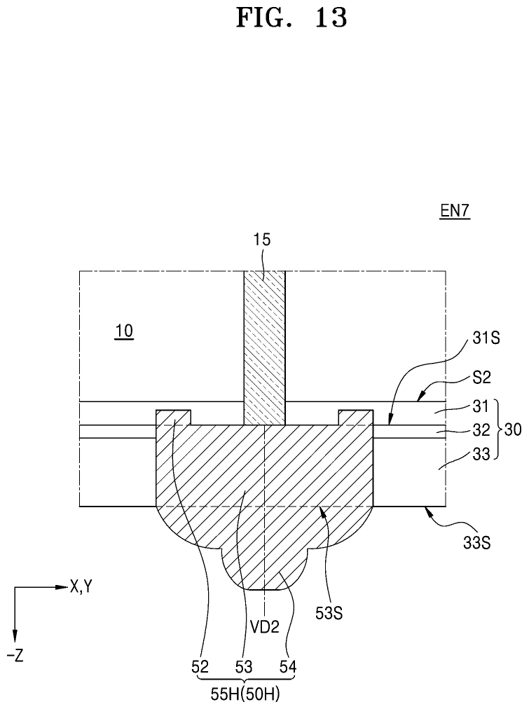

FIG. 11 is a cross-sectional view illustrating a semiconductor chip 100A-H according to some implementations. FIG. 12 is an enlarged view of an EN6 region of FIG. 11. FIG. 13 is an enlarged view of an EN7 region of FIG. 11.

Specifically, the semiconductor chip 100A-H may be almost the same as the semiconductor chip 100A of FIGS. 1 to 3, except that a front pad structure 40H further includes a third front pad pattern 44, and a back pad structure 50H further includes a third back pad pattern 54.

In FIGS. 11 to 13, reference numerals identical to or similar to those of FIGS. 1 to 3 indicate the same or similar members. In FIGS. 11 to 13, descriptions given with reference to FIGS. 1 to 3 are briefly explained or omitted. The cross-sectional view of the semiconductor chips 100A-H shown in FIGS. 11 to 13 may be at a high temperature, for example, 200° C.

As shown in FIGS. 11 and 12, the semiconductor chip 100A-H may include the front insulating structure 20 and the front pad structure 40H disposed on the front surface S1 of the body 10. The front insulating structure 20 may include the front passivation layer 21, the front etch stop layer 22, and the front bonding insulating layer 23.

The front pad structure 40H may be formed in the front insulating structure 20. The front pad structure 40H may include a front pad pattern 45H including a first front pad pattern 42, a second front pad pattern 43, and a third front pad pattern 44.

The first front pad pattern 42 may be located in the front passivation layer 21. The second front pad pattern 43 may be located in the front etch stop layer 22 and the front bonding insulating layer 23. The third front pad pattern 44 protrudes from a surface 43S of the second front pad pattern 43.

The third front pad pattern 44 protrudes from the surface 23S of the front bonding insulating layer 23. The third front pad pattern 44 may be formed by expanding the first front pad pattern 42 and the second front pad pattern 43 by high-temperature application of the semiconductor chip 100A of FIGS. 1 to 3.

The third front pad pattern 44 may have a symmetrical structure in the horizontal direction (X direction or Y direction) with respect to a reference line VD1 perpendicular to an upper surface of the first front pad pattern 42 or the upper metal pattern 13. Accordingly, the semiconductor chip 100A-H may improve a bonding reliability when bonding between the front pad structures 40H of a lower semiconductor chip and an upper semiconductor chip as described below.

As shown in FIGS. 11 and 13, the semiconductor chip 100A-H may include the back insulating structure 30 and the back pad structure 50H disposed on the back surface S2 of the body 10. The backside insulating structure 30 may include the backside passivation layer 31, the backside etch stop layer 32, and the backside bonding insulating layer 33.

The back pad structure 50H may be formed in the back insulating structure 30. The back pad structure 50H may include the back pad pattern 55H including a first back pad pattern 52, a second back pad pattern 53, and a third back pad pattern 54.

The first back pad pattern 52 may be located in the back passivation layer 31 on both sides of the through via 15. The second back pad pattern 53 may be located in the back etch stop layer 32 and the back bonding insulating layer 33. The third back pad pattern 54 protrudes from a surface 53S of the second back pad pattern 53.

The third back pad pattern 54 protrudes from the surface 33S of the back bonding insulating layer 33. The third back pad pattern 54 may be formed by expanding the first back pad pattern 52 and the second back pad pattern 53 by high-temperature application of the semiconductor chip 100A of FIGS. 1 to 3.

The third back pad pattern 54 may have a symmetrical structure in the horizontal direction (X direction or Y direction) with respect to a reference line VD2 perpendicular to a lower surface of the first back pad pattern 52 or the through via 15. Accordingly, the semiconductor chip 100A-H may improve the bonding reliability when bonding between the back pad structures 50H of the lower semiconductor chip and the upper semiconductor chip as described below.

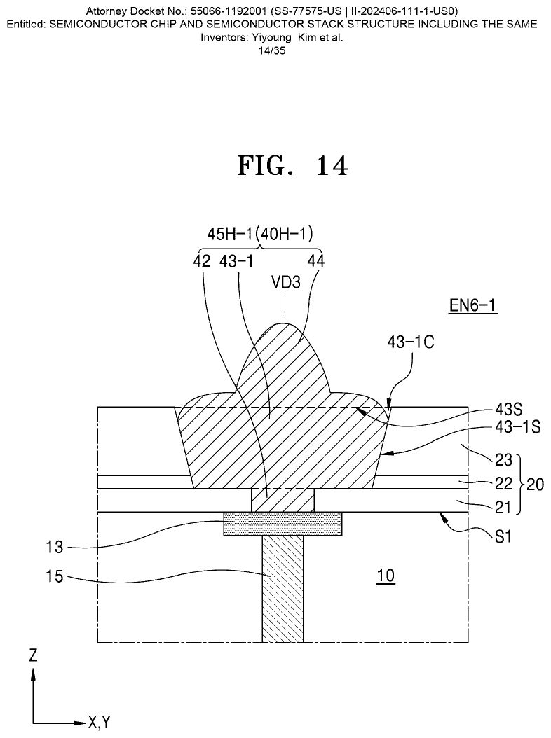

FIG. 14 is an enlarged view EN6-1 of FIG. 12 according to some implementations.

Specifically, the enlarged view EN6-1 of FIG. 14 may be almost the same as the enlarged view EN6 of FIG. 12, except that a structure of a front pad pattern 45H-1 constituting a front pad structure 40H-1 is different.

In other words, the enlarged view EN6-1 of FIG. 14 may be substantially the same as the enlarged view EN6 of FIG. 12 except that a structure of the second front pad pattern 43-1 constituting the front pad structure 40H-1 is different. In FIG. 14, reference numerals identical to or similar to those of FIG. 12 indicate the same or similar members. In FIG. 14, descriptions given with reference to FIG. 12 are briefly explained or omitted.

The front pad structure 40H-1 may include the front pad pattern 45H-1 including the first front pad pattern 42, the second front pad pattern 43-1, and the third front pad pattern 44. As shown in FIG. 14, the second front pad pattern 43-1 may have a width of an upper portion greater than a width of a lower portion. Accordingly, the one side surface 43-1S of the second front pad pattern 43-1 may be an inclined surface with a slope increasing upward. In some implementations, upper portions of both sides of the second front pad pattern 43-1 may include a contraction portion 43-1C.

In the front pad structure 40H-1 of the semiconductor chip 100A-H, the second front pad pattern 43-1 is configured to have the width of the upper portion greater than the width of the lower portion. Accordingly, the front pad structure 40H-1 of the semiconductor chip 100A-H has a large surface area, thereby improving a bonding reliability when bonding a lower semiconductor chip and an upper semiconductor chip as described below.

In the front pad structure 40H-1 of the semiconductor chip 100A-H, the third front pad pattern 44 may have a symmetrical structure in the horizontal direction (X direction or Y direction) with respect to a reference line VD3 perpendicular to an upper surface of the first front pad pattern 42 or the upper metal pattern 13. Accordingly, the semiconductor chip 100A-H may improve the bonding reliability when bonding between the front pad structure 40H-1 of the lower semiconductor chip and the upper semiconductor chip as described below.

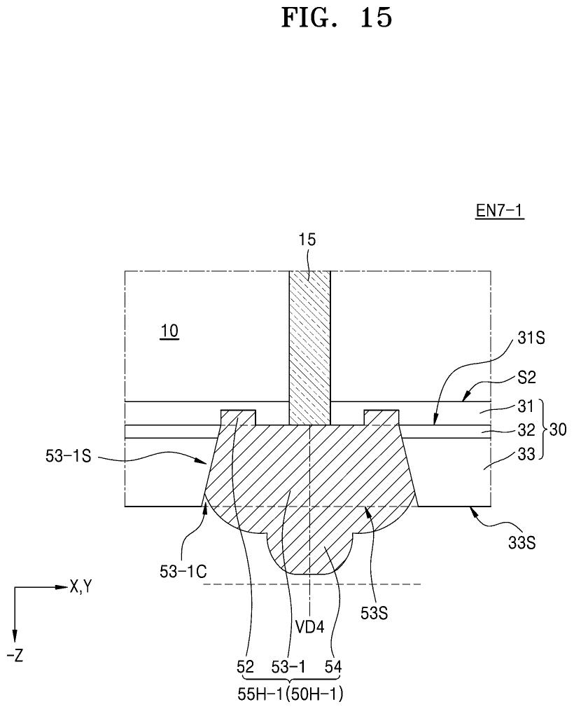

FIG. 15 is an enlarged view EN7-1 of FIG. 13 according to some implementations.

Specifically, the enlarged view EN7-1 of FIG. 15 is compared with an enlarged view EN7 of FIG. 13. Specifically, the enlarged view EN7-1 of FIG. 15 may be almost the same as the enlarged view EN7 of FIG. 13, except that a structure of the back pad pattern 55H-1 constituting the back pad structure 50H-1 is different.

In other words, an enlarged view EN7-1 of FIG. 15 is compared with an enlarged view EN7 of FIG. 13. In other words, the enlarged view EN7-1 of FIG. 15 may be substantially the same as the enlarged view EN7 of FIG. 13, except that a structure of the second back pad pattern 53-1 constituting the back pad structure 50H-1 is different. In FIG. 15, reference numerals identical to or similar to those of FIG. 13 indicate the same or similar members. In FIG. 15, descriptions given with reference to FIG. 13 are briefly explained or omitted.

The back pad structure 50H-1 may include a back pad pattern 55H-1 including the first back pad pattern 52, the second back pad pattern 53-1, and the third back pad pattern 54. As shown in FIG. 5, the second back pad pattern 53-1 may have a width of a lower portion greater than a width of an upper portion. Accordingly, the one side surface 53-1S of the second back pad pattern 53-1 may be an inclined surface with a slope increasing downward. In some implementations, lower portions of both sides of the second back pad pattern 53-1 may include a contraction portion 53-1C.

In the back pad structure 50H-1 of the semiconductor chip 100A-H, the second back pad pattern 53-1 is configured to have the width of the lower portion greater than the width of the upper portion. Accordingly, the back pad structure 50H-1 of the semiconductor chip 100A-H has a large surface area, thereby improving a bonding reliability when bonding a lower semiconductor chip and an upper semiconductor chip as described below.

In the back pad structure 50H-1 of the semiconductor chip 100A-H, the third back pad pattern 54 may have a symmetrical structure in the horizontal direction (X direction or Y direction) with respect to a reference line VD4 perpendicular to a lower surface of the second back pad pattern 53-1 or the through via 15. Accordingly, the semiconductor chip 100A-H may improve the bonding reliability when bonding between the back pad structure 50H-1 of the lower semiconductor chip and the upper semiconductor chip as described below.

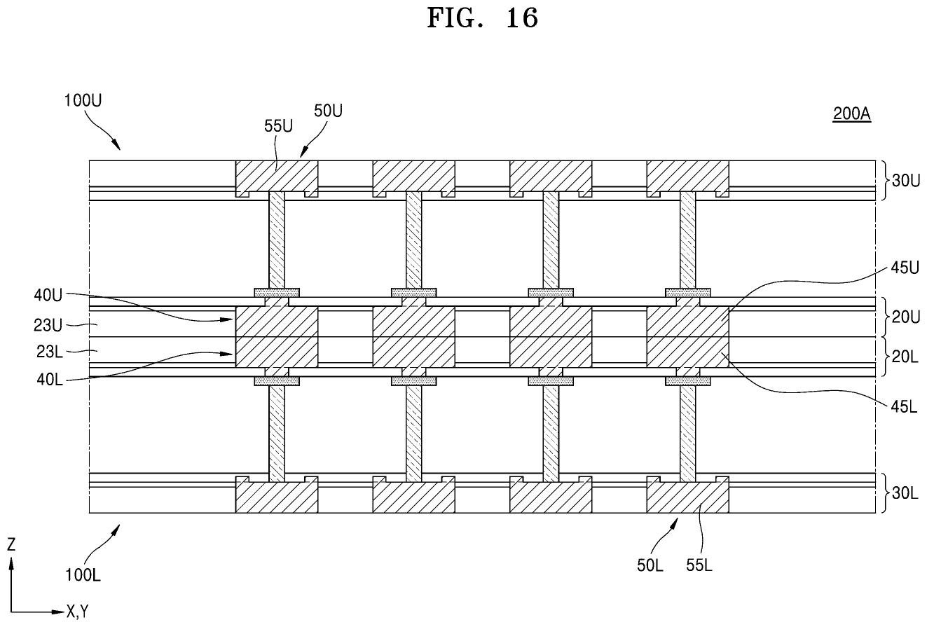

FIGS. 16 to 19 are cross-sectional views illustrating semiconductor stack structures 200A to 200D according to some implementations.

Specifically, the semiconductor stack structures 200A to 200D may include two stacked semiconductor chips 100L and 100U, respectively. The semiconductor stack structures 200A to 200D may include a lower semiconductor chip 100L and an upper semiconductor chip 100U.

The upper semiconductor chip 100U may be hybrid-bonded on the lower semiconductor chip 100L with a high bonding reliability by using the front insulating structure 20, the front pad structures 40 and 40H, the back insulating structure 30, and the back pad structures 50 and 50H described above. In FIGS. 16 to 19, reference numerals identical to or similar to those of the previous drawings indicate the same or similar members. In FIGS. 16 to 19, descriptions given above are briefly explained or omitted.

Referring to FIG. 16, the semiconductor stack structure 200A may include the lower semiconductor chip 100L and the upper semiconductor chip 100U bonded and stacked in a face-to-face manner. For example, a front insulating structure 20L of the lower semiconductor chip 100L and a front insulating structure 20U of the upper semiconductor chip 100U may be in contact with and bonded to each other. A front pad structure 40L of the lower semiconductor chip 100L and a front pad structure 40U of the upper semiconductor chip 100U may be in contact with and bonded to each other.

More specifically, a front bonding insulating layer 23L of the lower semiconductor chip 100L and a front bonding insulating layer 23U of the upper semiconductor chip 100U may be in direct contact with and bonded to each other at room temperature, for example, 25° C. A front pad pattern 45L of the front pad structure 40L of the lower semiconductor chip 100L and a front pad pattern 45U of the front pad structure 40U of the upper semiconductor chip 100U may be in contact with and bonded to each other at a high temperature, for example, 200° C.

The lower semiconductor chip 100L may be bonded in a face-up manner, and the upper semiconductor chip 100U may be bonded in a face-down manner. The lower semiconductor chip 100L may include a back pad structure 50L and a back pad pattern 55L. The upper semiconductor chip 100U may include a back pad structure 50U and a back pad pattern 55U.

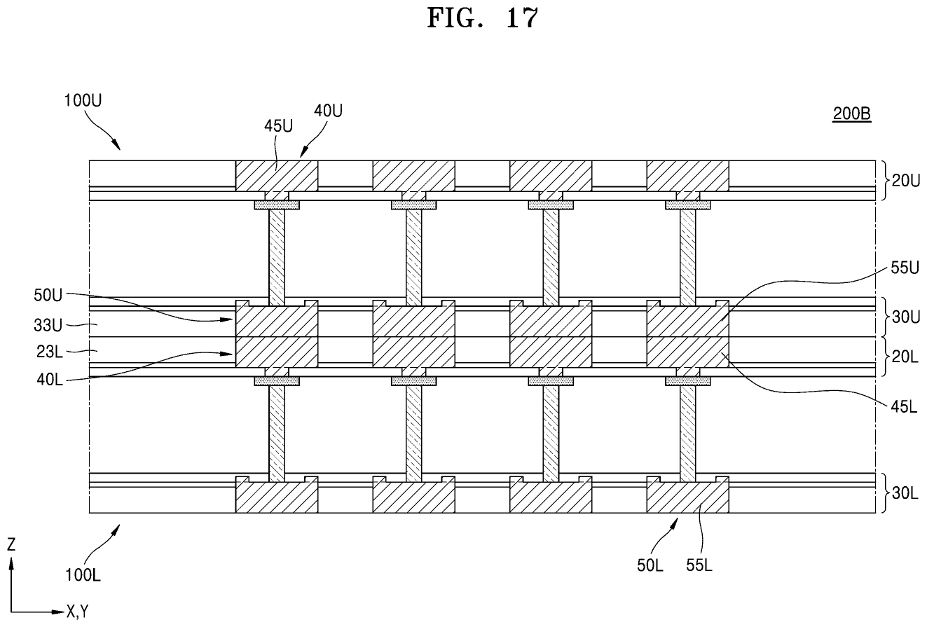

Referring to FIG. 17, the semiconductor stack structure 200B may include the lower semiconductor chip 100L and the upper semiconductor chip 100U bonded and stacked in a face-to-back manner. For example, the front insulating structure 20L of the lower semiconductor chip 100L and a back insulating structure 30U of the upper semiconductor chip 100U may be in contact with and bonded to each other. The front pad structure 40L of the lower semiconductor chip 100L and a back pad structure 50U of the upper semiconductor chip 100U may be in contact with and bonded to each other.

In more detail, the front bonding insulating layer 23L of the lower semiconductor chip 100L and a back bonding insulating layer 33U of the upper semiconductor chip 100U may be in direct contact with and bonded to each other at room temperature, for example, 25° C. The front pad pattern 45L of the front pad structure 40L of the lower semiconductor chip 100L and a back pad pattern 55U of the back pad structure 50U of the upper semiconductor chip 100U may be in contact with and bonded to each other at a high temperature, for example, 200° C.

Both the lower semiconductor chip 100L and the upper semiconductor chip 100U may be bonded in a face-up manner. The lower semiconductor chip 100L may include the back pad structure 50L and the back pad pattern 55L. The upper semiconductor chip 100U may include the front pad structure 40U and the front pad pattern 45U.

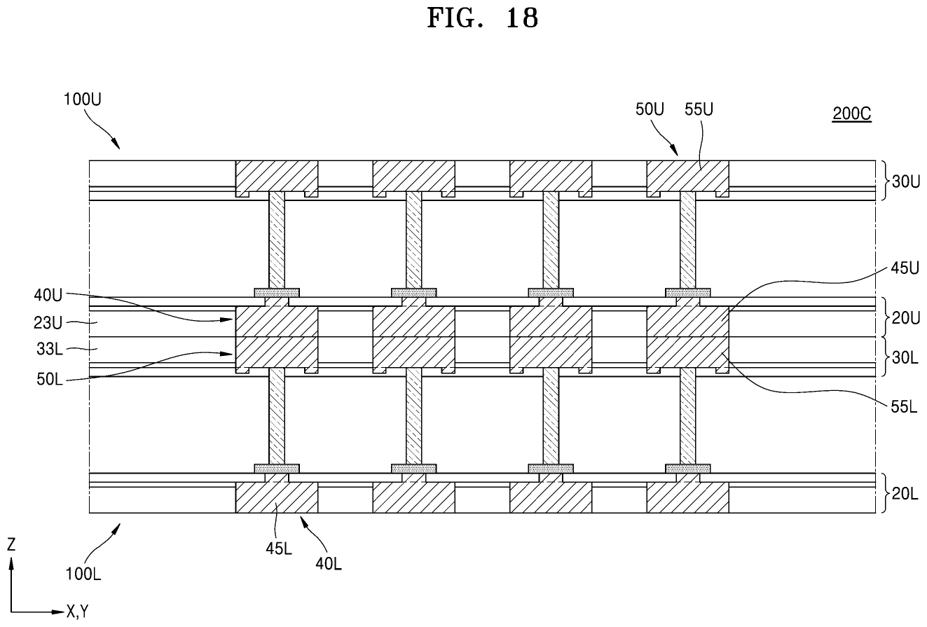

Referring to FIG. 18, the semiconductor stack structure 200C may include the lower semiconductor chip 100L and the upper semiconductor chip 100U bonded and stacked in a back-to-face manner. For example, a back insulating structure 30L of the lower semiconductor chip 100L and the front insulating structure 20U of the upper semiconductor chip 100U may be in contact with and bonded to each other. The back pad structure 50L of the lower semiconductor chip 100L and the front pad structure 40U of the upper semiconductor chip 100U may be in contact with and bonded to each other.

More specifically, a back bonding insulating layer 33L of the lower semiconductor chip 100L and a front bonding insulating layer 23U of the upper semiconductor chip 100U may be in direct contact with and bonded to each other at room temperature, for example, 25° C. The back pad pattern 55L of the back pad structure 50L of the lower semiconductor chip 100L and the front pad pattern 45U of the front pad structure 40U of the upper semiconductor chip 100U may be in contact with and bonded to each other at a high temperature, for example, 200° C.

Both the lower semiconductor chip 100L and the upper semiconductor chip 100U may be bonded in a face-down manner. The lower semiconductor chip 100L may include the front pad structure 40L and the front pad pattern 45L. The upper semiconductor chip 100U may include the back pad structure 50U and the back pad pattern 55U.

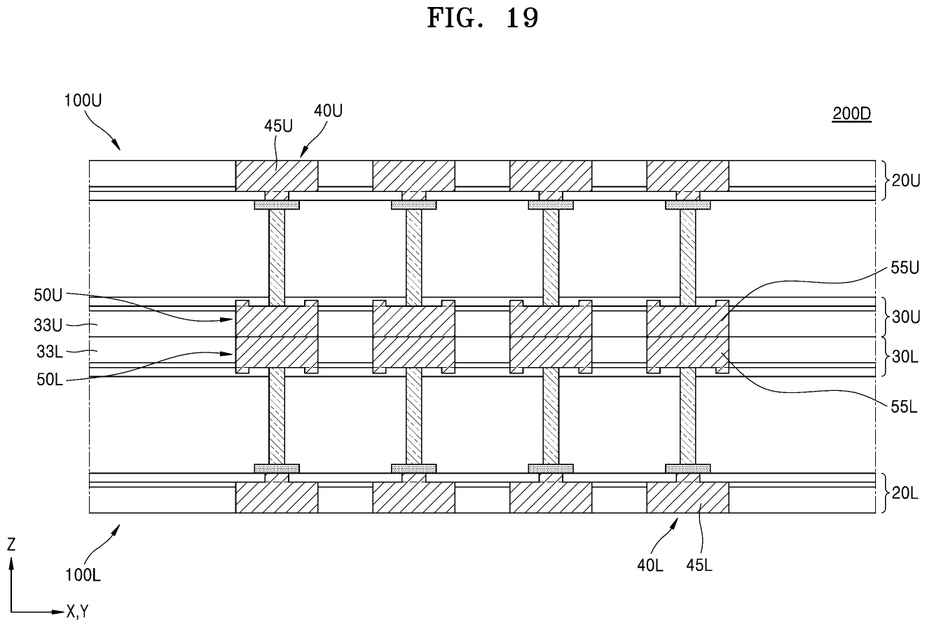

Referring to FIG. 19, the semiconductor stack structure 200D may include the lower semiconductor chip 100L and the upper semiconductor chip 100U bonded and stacked in a back-to-back manner. For example, the back insulating structure 30L of the lower semiconductor chip 100L and the back insulating structure 30U of the upper semiconductor chip 100U may be in contact with and bonded to each other. The back pad structure 50L of the lower semiconductor chip 100L and the back pad structure 50U of the upper semiconductor chip 100U may be in contact with and bonded to each other.

More specifically, the back bonding insulating layer 33L of the lower semiconductor chip 100L and the back bonding insulating layer 33U of the upper semiconductor chip 100U may be in direct contact with and bonded to each other at room temperature, for example, 25° C. The back pad pattern 55L of the back pad structure 50L of the lower semiconductor chip 100L and the back pad pattern 55U of the back pad structure 50U of the upper semiconductor chip 100U may be in contact with and bonded to each other at a high temperature, for example, 200° C.

The lower semiconductor chip 100L may be bonded in a face-down manner, and the upper semiconductor chip 100U may be bonded in a face-up manner. The lower semiconductor chip 100L may include the front pad structure 40L and the front pad pattern 45L. The upper semiconductor chip 100U may include the front pad structure 40U and the front pad pattern 45U.

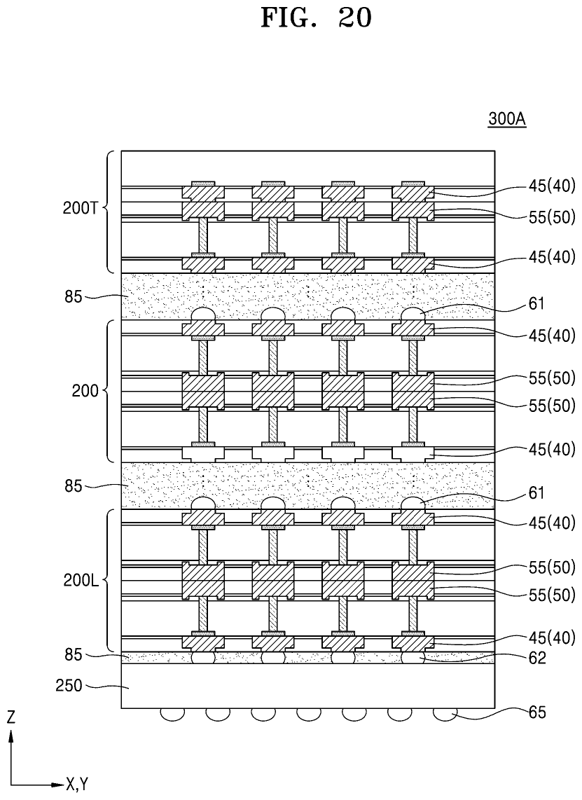

FIGS. 20 to 23 are cross-sectional views illustrating semiconductor stack structures 300A to 300D according to some implementations.

Specifically, the semiconductor stack structures 300A to 300D may include a plurality of unit semiconductor stack structures 200, 200L, and 200T stacked on a base chip 250. The unit semiconductor stack structures 200, 200L and 200T may include any one of the semiconductor stack structures 200A to 200D shown in FIGS. 16 to 19.

In FIGS. 20 to 23, reference numerals identical to or similar to those of the previous drawings indicate the same or similar members. In FIGS. 20 to 23, descriptions given above are briefly explained or omitted.

Referring to FIG. 20, the semiconductor stack structure 300A may include the plurality of unit semiconductor stack structures 200, 200L, and 200T stacked on the base chip 250. The front and back pad patterns 45 and 55 of the front and back pad structures 40 and 50 of the unit semiconductor stack structures 200, 200L, and 200T may be physically bonded and electrically connected to each other through inner bumps 61.

The base chip 250 and the lowermost unit semiconductor stack structure 200L may be bonded and connected to each other through outer bumps 62. The base chip 250 may include base bumps 65 to be connected to an external interposer. The inner bumps 61, the outer bumps 62, and the base bumps 65 may include solder balls.

Spaces between the unit semiconductor stack structures 200, 200L, and 200T or spaces between the inner bumps 61 and the outer bumps 62 may be filled with an underfill layer 85. The underfill layer 85 may be an insulating material including a thermosetting resin such as an epoxy resin.

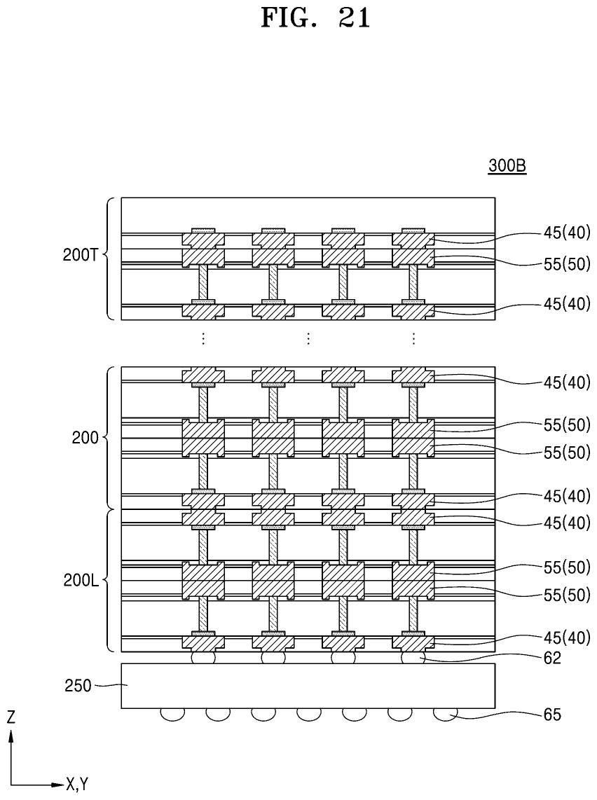

Referring to FIG. 21, the semiconductor stack structure 300B may include the plurality of unit semiconductor stack structures 200, 200L, and 200T stacked on and bonded to the base chip 250 using a hybrid bonding method.

The front pad pattern 45 and the back pad pattern 55 of the front pad structure 40 and the back pad structure 50 of the unit semiconductor stack structures 200, 200L, and 200T may be in direct contact with and bonded to each other. The front bonding insulating layer 23 and the back bonding insulating layer 33 of the unit semiconductor stack structures 200, 200L, and 200T may be in direct contact with and bonded to each other.

The base chip 250 and the lowermost unit semiconductor stack structure 200L may be bonded using external bumps 62. The base chip 250 may include base bumps 65 to be connected to an external interposer.

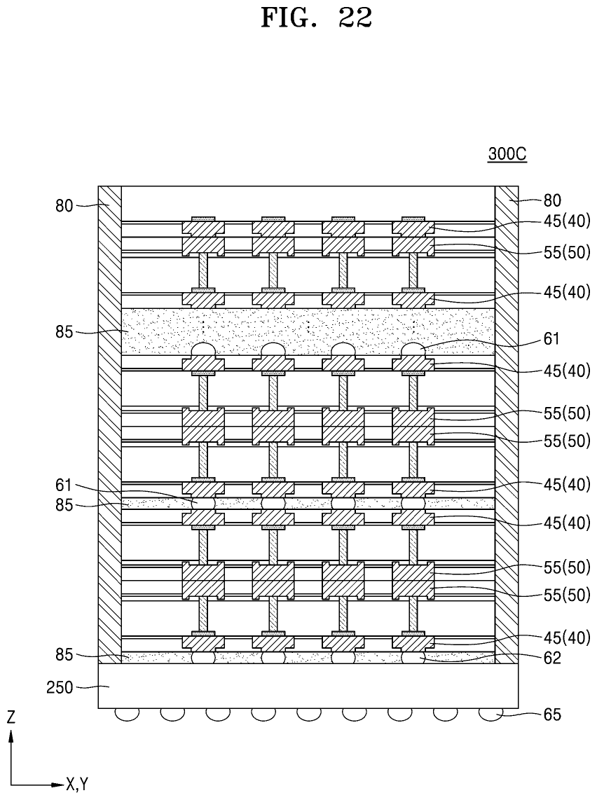

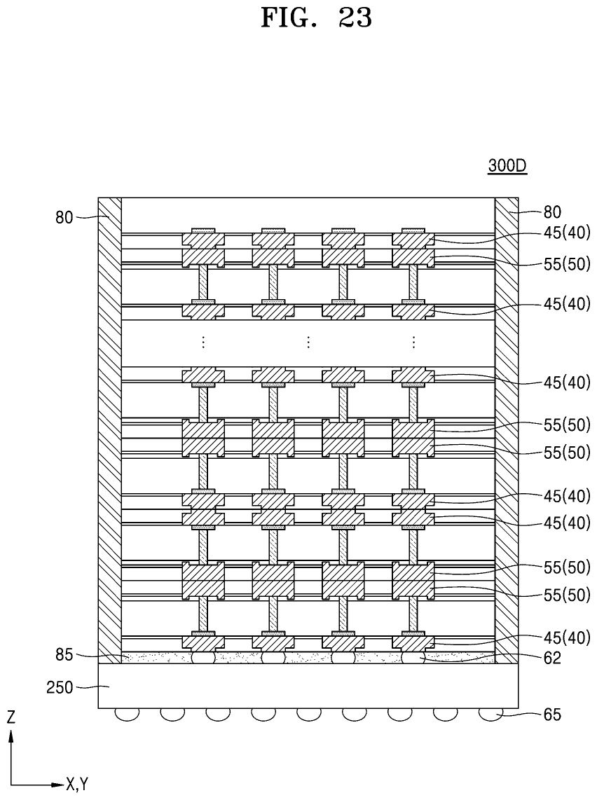

Referring to FIGS. 22 and 23, the semiconductor stack structures 300C and 300D may further include a heat dissipation molding layer 80 formed on side surfaces of the unit semiconductor stack structures 200, 200L and 200T. The heat dissipation molding layer 80 may be in contact with an upper surface of the base chip 250.

The heat dissipation molding layer 80 may include an epoxy resin and an aluminum nitride (AlN) filler. An aluminum nitride (AlN) filler has better thermal conductivity than a silica (SiO₂) filler and an alumina (Al₂O₃) filler. The heat dissipation molding layer 80 may dissipate heat generated from the unit semiconductor stack structures 200, 200L, and 200T to the outside better than a molding layer including silica or alumina. In some implementations, the heat dissipation molding layer 80 may further include carbon (C).

The spaces between the inner bumps 61 and between the outer bumps 62 may be filled with the underfill layer 85. The underfill layer 85 may be an insulating material including a thermosetting resin such as an epoxy resin.

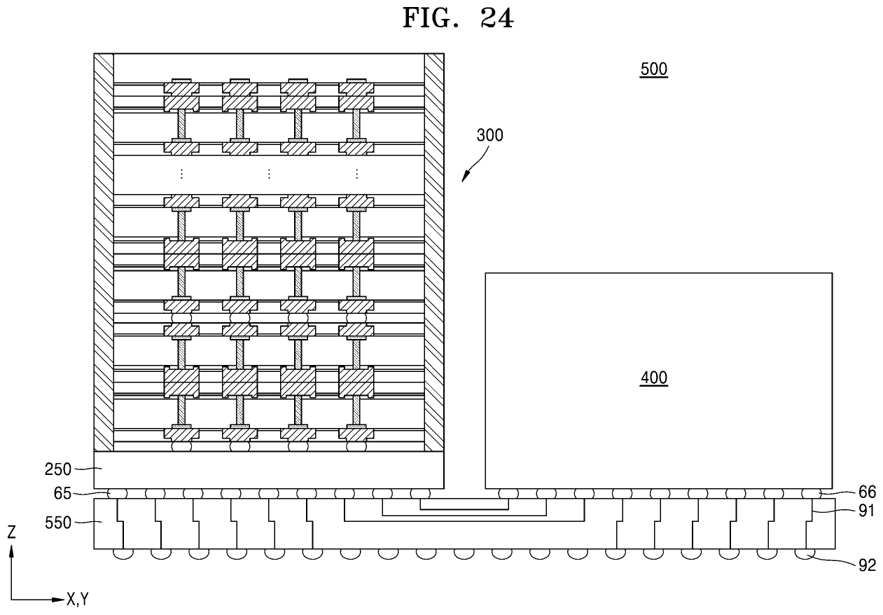

FIG. 24 is a cross-sectional view for explaining a memory device 500 including a semiconductor stack structure 300 according to some implementations.

Specifically, the memory device 500 may be a high bandwidth memory device. The memory device 500 may include a semiconductor stack structure 300 and a processing device 400 disposed on an interposer 550.

The interposer 550 may include a PCB substrate. The semiconductor stack structure 300 may be any one of the semiconductor stack structures 300A to 300D shown in FIGS. 20 to 23. The interposer 550 may include interposer wirings 91.

The semiconductor stack structure 300 and the processor 400 may electrically communicate with each other through the base bumps 65, an interposer wiring 91, and processor bumps 66. The interposer 550 may communicate with an external system through interposer bumps 92.

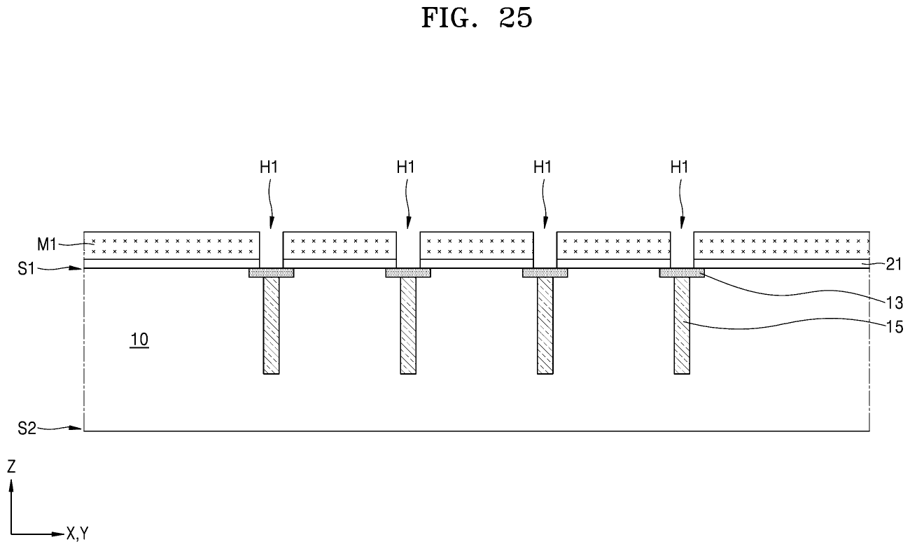

FIGS. 25 to 34 are cross-sectional views illustrating a method of manufacturing a semiconductor chip according to some implementations.

Specifically, FIGS. 25 to 34 may be some implementations of the method of manufacturing the semiconductor chip 100A of FIGS. 1 to 3. In FIGS. 25 to 34, reference numerals identical to or similar to those of FIGS. 1 to 3 indicate the same or similar members. In FIGS. 25 to 34, descriptions given with reference to FIGS. 1 to 3 are briefly explained or omitted.

Referring to FIG. 25, the body 10 including the upper metal pattern 13 and the through via 15 is prepared. The front passivation layer 21 is formed on the front surface S1 of the body 10. A first mask pattern M1 is formed on the front passivation layer 21.

A first front hole H1 partially exposing an upper surface of the upper metal pattern 13 is formed by etching a part of the front passivation layer 21 using the first mask pattern M1 as an etch mask. The first front hole H1 may be aligned with the upper metal pattern 13 and the through via 15 in the vertical direction (Z direction).

The front surface S1 of the body 10 may be an active surface, for example, a surface of insulating layers covering a circuit structure such as a transistor formed on an upper surface of a silicon wafer. The back surface S2 of the body 10 may be a lower surface of the silicon wafer on which no circuit structure is formed.

The upper metal pattern 13 may be disposed in the body 10. The upper metal pattern 13 may be an uppermost metal layer of a semiconductor circuit. The upper metal pattern 13 may include a metal such as aluminum (Al) or tungsten (W). A lower surface of the upper metal pattern 13 may be in contact with an upper end of the through via 15.

The through via 15 may vertically extend into the body 10 and may be vertically aligned with the upper metal pattern 13. The through via 15 may include a metal layer, for example, copper (Cu). An insulating via liner (not shown) may be further formed on a side surface of the through via 15. The insulating via liner may electrically insulate the through via 15 from the body 10. A lower end of the through via 15 may be located in the body 10.

The front passivation layer 21 may be formed to be flat on the front surface S1 of the body 10. The front passivation layer 21 may expose a part of the upper surface of the upper metal pattern 13. The front passivation layer 21 may include a silicon oxide-based inorganic insulating layer or a polyimide-based polymer organic insulating layer. The first mask pattern M1 may be formed using a photolithography process. The first mask pattern M1 may be a photoresist pattern.

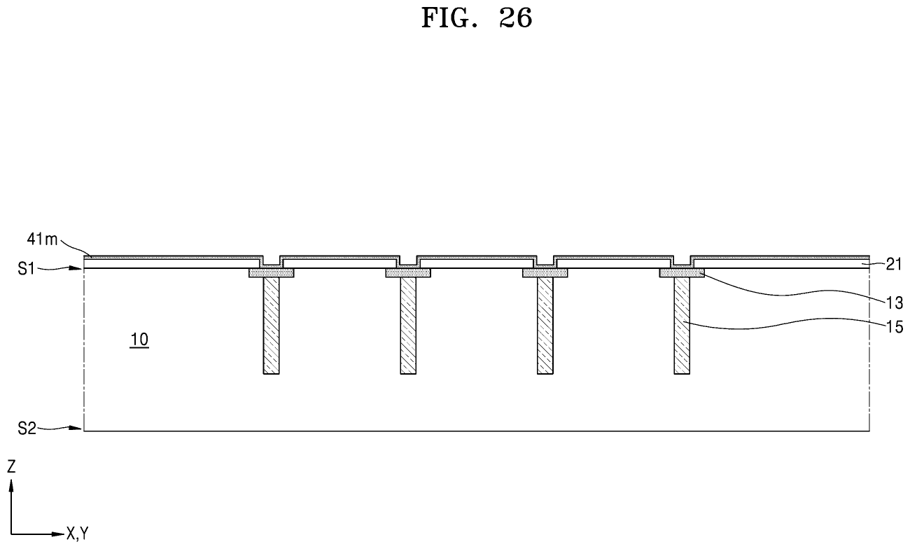

Referring to FIG. 26, after the first mask pattern M1 (FIG. 25) is removed, a front pad seed material layer 41m is conformally formed on the upper surface of the front passivation layer 21 and the upper surface of the upper metal pattern 13. The front pad seed material layer 41m may be formed by performing a physical vapor deposition (PVD) process such as sputtering. The front pad seed material layer 41m may include copper (Cu). The front pad seed material layer 41m may also be formed on a sidewall of the front passivation layer 21 in the first front hole H1 of FIG. 25.

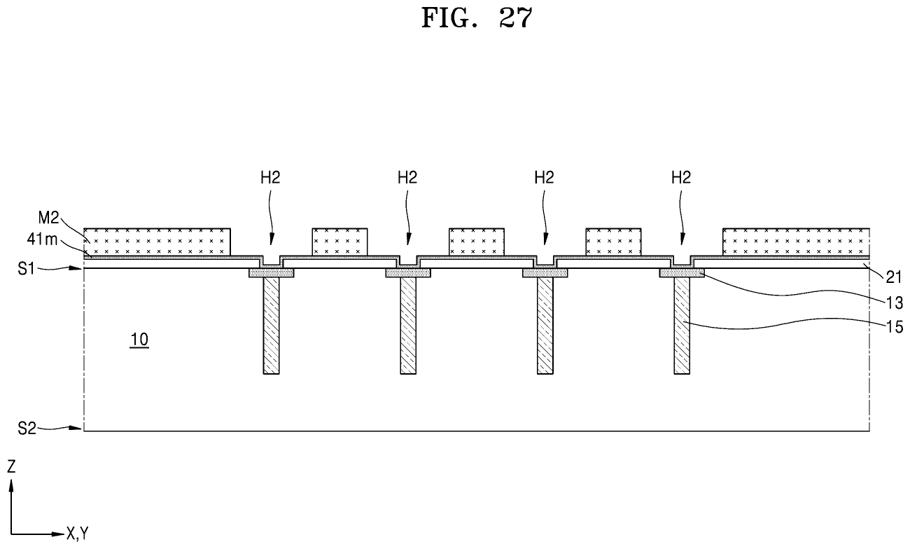

Referring to FIG. 27, a second mask pattern M2 having a second front hole H2 is formed by performing a photolithography process. The second mask pattern M2 may also be a photoresist pattern. The second front hole H2 may be aligned with the upper metal pattern 13 and the through via 15 in the vertical direction (Z direction). The second front hole H2 may expose a part of the front pad seed material layer 41m on the upper metal pattern 13 and the through via 15.

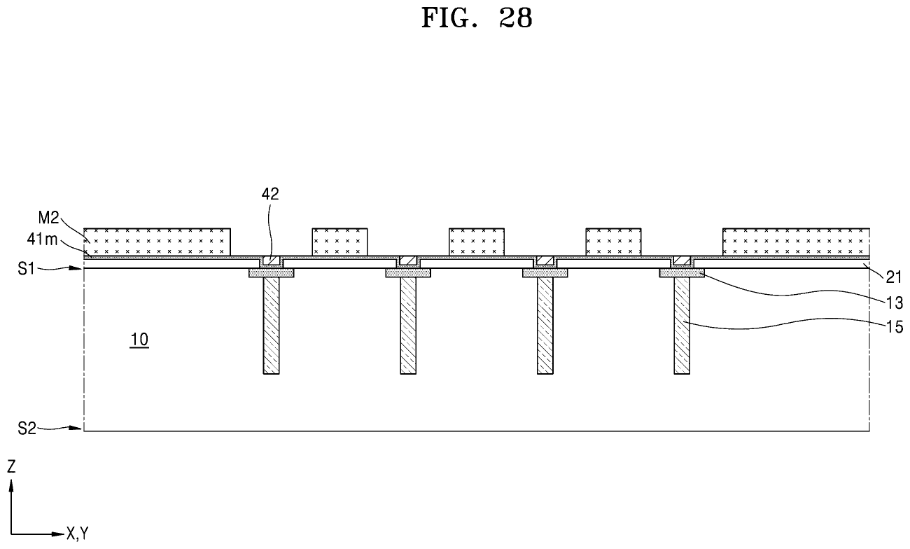

Referring to FIG. 28, the first front pad pattern 42 is formed on the front pad seed material layer 41m in the first front hole H1 (FIG. 25) and the second front hole H2 by performing a plating process. The first front pad pattern 42 may be formed in the first front hole H1 (FIG. 25) on the through via 15 and the upper metal pattern 13. The first front pad pattern 42 may be formed using a metal layer, for example, a copper layer.

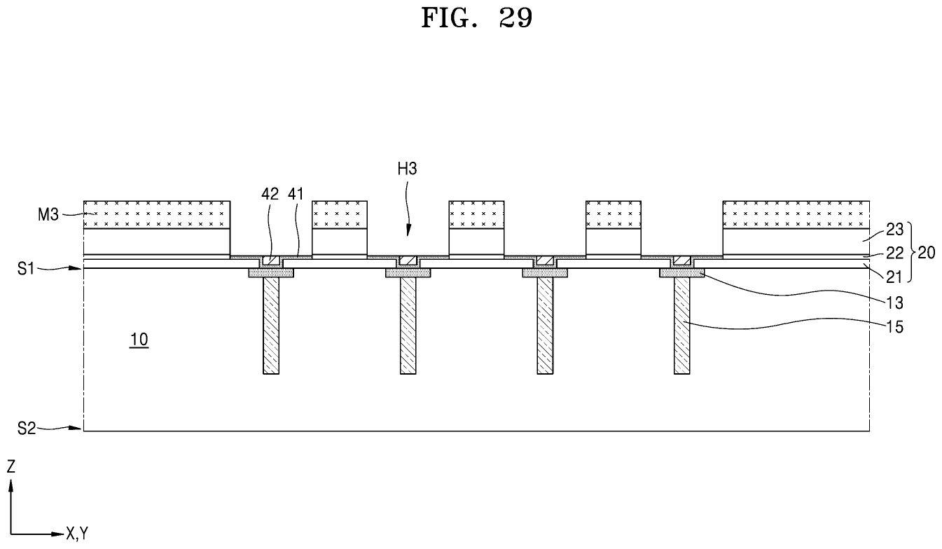

Referring to FIG. 29, the second mask pattern M2 (FIG. 28) is removed. A front etch stop material layer and a front bonding insulating material layer may be formed on the front passivation layer 21, the first front pad pattern 42, and the front pad seed material layer 41m. The front etch stop material layer may include an insulating material layer such as silicon nitride. The front bonding material layer may include an insulating material layer such as silicon oxide.

A third mask pattern M3 is formed on the front bonding material layer. The third mask pattern M3 may be a photoresist pattern. The front etch stop material layer, the front bonding insulating material layer, and the front pad seed material layer 41m are etched using the third mask pattern M3 as an etch mask.

Accordingly, the front etch stop layer 22 and the front bonding insulating layer 23 are formed on the front passivation layer 21. The front pad seed layer 41 and the first front pad pattern 42 may be formed on the through via 15 and the upper metal pattern 13. The front passivation layer 21, the front etch stop layer 22, and the front bonding insulating layer 23 constitute the front insulating structure 20.

In addition, a third front hole H3 exposing the front pad seed layer 41 and the first front pad pattern 42 may be formed on the through via 15 and the upper metal pattern 13. The third front hole H3 may be formed inside the front etch stop layer 22 and the front bonding insulating layer 23.

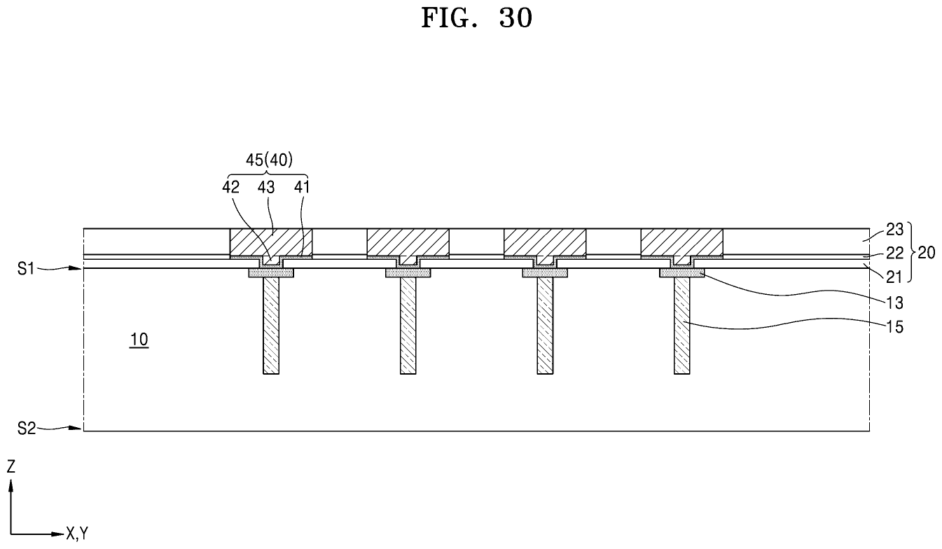

Referring to FIG. 30, the third mask pattern M3 is removed. The second front pad pattern 43 is formed in the third front hole H3. The second front pad pattern 43 may be formed by forming a second front pad material layer, for example, a copper layer, to fill the third front hole H3, and then planarizing and etching the second front pad material layer.

The second front pad pattern 43 may be formed on the first front pad pattern 42 and the front pad seed layer 41 in the third front hole H3. The first front pad pattern 42, the front pad seed layer 41, and the second front pad pattern 45 may include the same material. In FIG. 1 and FIG. 2, the front pad seed layer 41 is not shown for convenience.

Through the above process, the front pad pattern 45 including the front pad seed layer 41, the first front pad pattern 42, and the second front pad pattern 43 may be formed. The front pad pattern 45 constitutes the front pad structure 40.

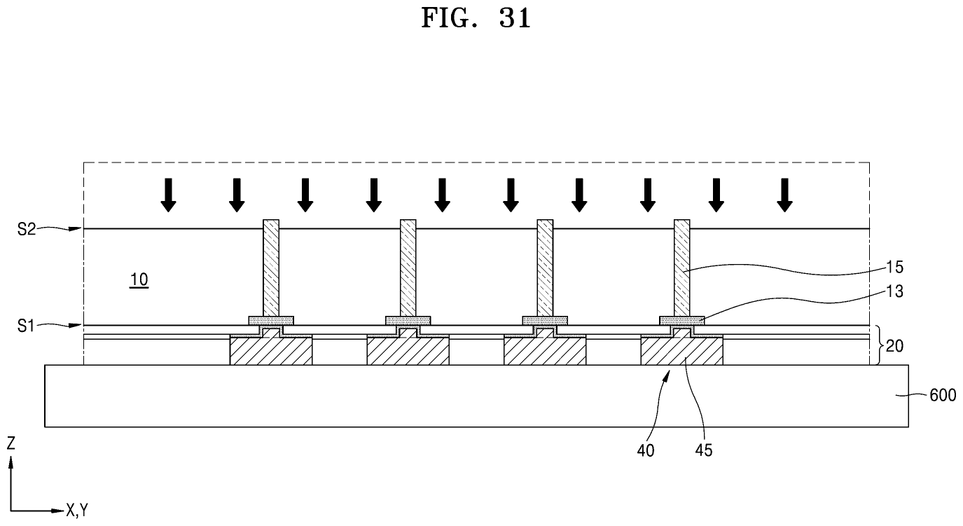

Referring to FIG. 31, a resultant of FIG. 30 is disposed upside down such that the front pad structure 40 and the front insulating structure 20 face downward on a carrier substrate 600. Subsequently, the back surface S2 of the body 10 is etched.

The etching of the back surface S2 of the body 10 may be performed using a grinding process or a chemical mechanical polishing process. An end portion of the through via 15 may protrude upward from the back surface S2 of the body 10 according to the etching of the back surface S2 of the body 10.

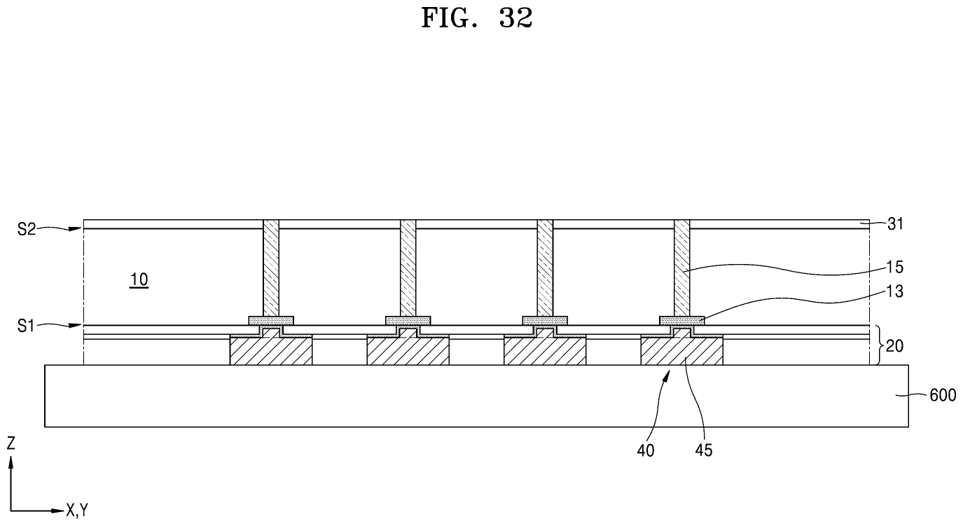

Referring to FIG. 32, the back passivation layer 31 is formed on the back surface S2 of the body 10. The end portion of the through via 15 may be buried inside the back passivation layer 31 so that the upper surface of the through via 15 is exposed on the back passivation layer 31. The upper surface of the through via 15 and the upper surface of the back passivation layer 31 may be the same plane. If the resultant of FIG. 32 is disposed upside down, the lower surface of the through via 15 and the lower surface of the back passivation layer 31 may be the same plane.

The back passivation layer 31 may be formed by forming a back passivation material layer such as silicon oxide and then planarizing and etching the back passivation material layer. A chemical mechanical polishing process may be used for planarization etching.

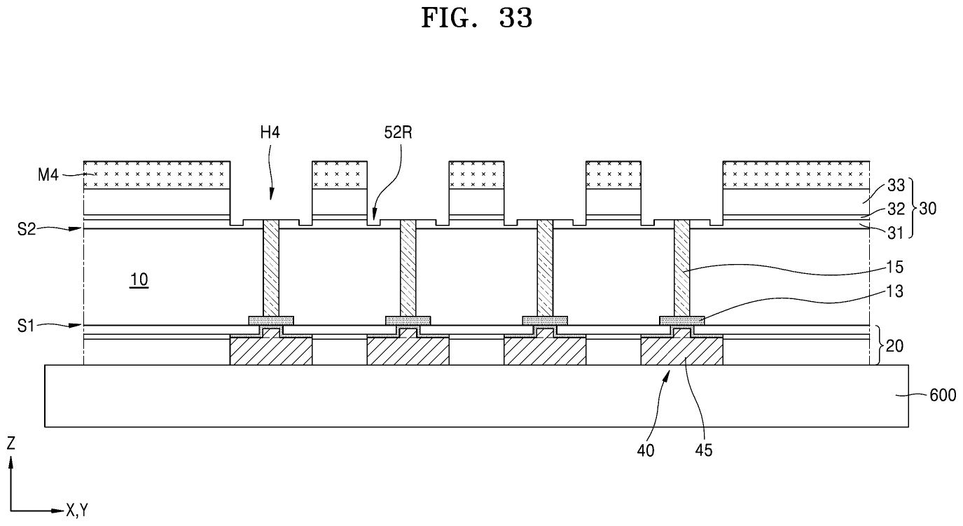

Referring to FIG. 33, a back etch stop material layer and a back bonding insulating material layer may be formed on the back passivation layer 31 and the through via 15. The back etch stop material layer may include an insulating material layer such as silicon nitride. The back bonding material layer may include an insulating material layer such as silicon oxide.

A fourth mask pattern M4 is formed on the back bonding material layer. The fourth mask pattern M4 may be a photoresist pattern. A part of the back bonding insulating material layer, the back etch stop material layer, and the back passivation layer 31 is etched using the fourth mask pattern M4 as an etch mask.

Accordingly, the back etch stop layer 32 and the back bonding insulating layer 33 are formed on the back passivation layer 31. The back passivation layer 31, the back etch stop layer 32, and the back bonding insulating layer 33 constitute the back insulating structure 30.

In addition, a back hole H4 exposing the through via 15 and the back passivation layer 31 may be formed on the through via 15 and the upper metal pattern 13. The back hole H4 may be formed inside the back etch stop layer 32 and the back bonding insulating layer 33.

In addition, the recess hole 52R is formed in the back passivation layer 31. The recess hole 52R may be formed by over-etching the back passivation layer 31 using the fourth mask pattern M4 as an etch mask.

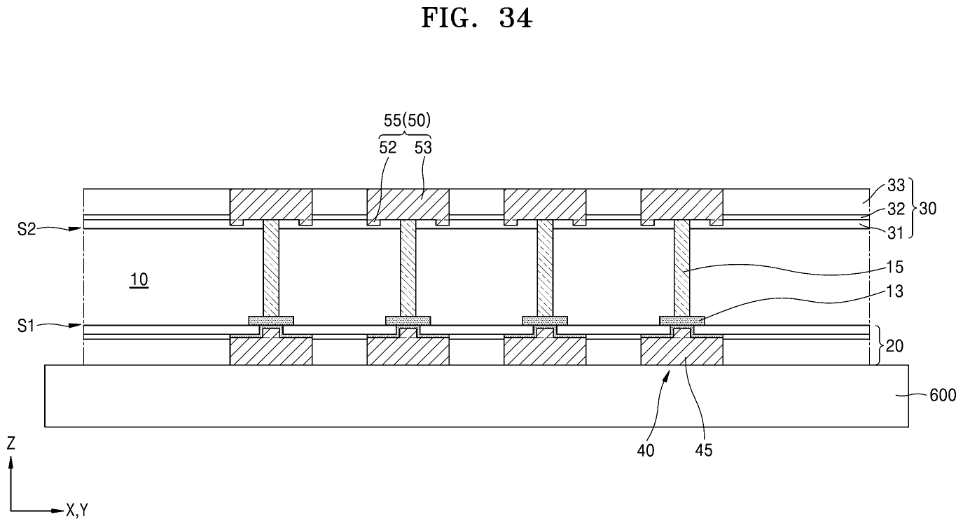

Referring to FIG. 34, the fourth mask pattern M4 is removed. The first back pad pattern 52 and the second back pad pattern 53 are formed in the recess hole 52R and the back hole H4. The first back pad pattern 52 and the second back pad pattern 53 may be formed by forming a back pad material layer, for example, a copper layer, to fill the recess hole 52R and the back hole H4, and then planarizing and etching the back pad material layer. In some implementations, a back pad seed layer may be further formed in the recess hole 52R and the back hole H4.

The first back pad pattern 52 may be formed in the recess hole 52R. The second back pad pattern 53 may be formed on the first back pad pattern 52 and the through via 15 in the back hole H4. The first back pad pattern 52 and the second back pad pattern 53 may include the same material.

Through the above process, the back pad pattern 55 including the first back pad pattern 52 and the second back pad pattern 53 may be formed. The back pad pattern 55 constitutes the back pad structure 40.

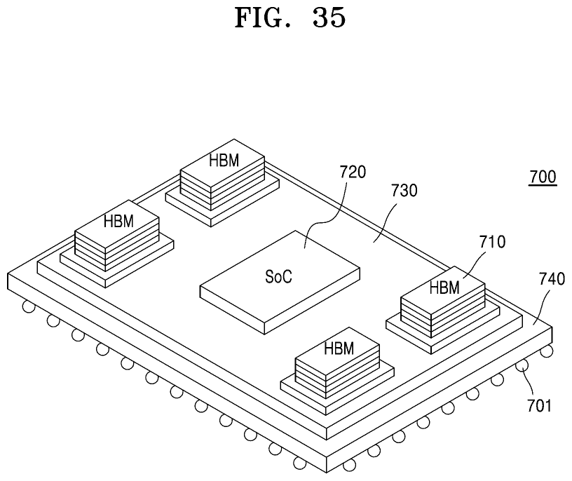

FIG. 35 is a diagram illustrating a semiconductor package 700 including a semiconductor stack structure according to some implementations.

Specifically, the semiconductor package 700 may include a plurality of stacked memory devices 710 and a system on chip 720. The stacked memory devices 710 and the system on chip 720 may be stacked on an interposer 730. The interposer 730 may be stacked on a package substrate 740. The semiconductor package 700 may transmit and receive signals to and from other external packages or electronic devices through a solder ball 701 attached to a lower portion of the package substrate 740.

Each of the stacked memory devices 710 may be implemented based on a HBM standard. However, the disclosure is not limited thereto, and each of the stacked memory devices 710 may be implemented based on GDDR, HMC, or Wide I/O standard. Each of the stacked memory devices 710 may include semiconductor stack structures according to some implementations.

The system on chip 720 may include at least one processor such as a CPU, an AP, a GPU, and an NPU, and a plurality of memory controllers for controlling the plurality of stacked memory devices 710. The system on chip 720 may transmit and receive signals to and from the corresponding stacked memory device 710 through a memory controller.

While this specification contains many specific implementation details, these should not be construed as limitations on the scope of any disclosure or on the scope of what may be claimed, but rather as descriptions of features that may be specific to particular implementations of particular disclosures. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to some implementations thereof, it will be understood that various changes in form and details may be made therein without departing from the spirit and scope of the following claims.

What is claimed is:

1. A semiconductor chip comprising:
a body having a front surface and a back surface;
a back insulating structure on the back surface of the body, the back insulating structure comprising a back passivation layer, a back etch stop layer and a back bonding insulating layer, sequentially disposed on the back surface; and
a back pad structure in the back insulating structure, the back pad structure comprising:
a plurality of first back pad patterns spaced apart from each other in a horizontal direction in the back passivation layer; and
a second back pad pattern below the plurality of first back pad patterns, wherein the second back pad pattern has a width and a thickness greater than a width and a thickness of each of the plurality of first back pad patterns.

2. The semiconductor chip of claim 1, wherein each of the plurality of first back pad patterns is located in a respective recess hole that is recessed from a surface of the back passivation layer.

3. The semiconductor chip of claim 1, wherein
an upper surface of each of the plurality of first back pad patterns is disposed higher than an upper surface of the second back pad pattern.

4. The semiconductor chip of claim 1, wherein an upper surface of each of the plurality of first back pad patterns is spaced apart from the back surface of the body in a vertical direction.

5. The semiconductor chip of claim 1, wherein the plurality of first back pad patterns and the second back pad pattern include a same material.

6. The semiconductor chip of claim 1, wherein a width of an upper portion of the second back pad pattern is different from a width of a lower portion of the second back pad pattern.

7. The semiconductor chip of claim 1, wherein the back pad structure further includes a third back pad pattern protruding from a surface of the second back pad pattern.

8. The semiconductor chip of claim 7, wherein the third back pad pattern has a symmetrical structure in the horizontal direction.

9. The semiconductor chip of claim 1, further comprising:
a front insulating structure on the front surface of the body,
wherein the front insulating structure comprises a front passivation layer, a front etch stop layer and a front bonding insulating layer, sequentially disposed on the front surface; and
a front pad structure in the front insulating structure.

10. A semiconductor chip comprising:
a body having a front surface and a back surface;
a through via extending through the front surface and the back surface;
a back insulating structure on the back surface of the body and surrounding the through via, the back insulating structure comprising a back passivation layer, a back etch stop layer and a back bonding insulating layer, sequentially disposed on the back surface; and
a back pad structure in the back insulating structure,
wherein the back pad structure comprises:
a plurality of first back pad patterns spaced apart from each other in a horizontal direction in the back passivation layer and spaced apart from the through via in the horizontal direction, and
a second back pad pattern below the plurality of first back pad patterns and the back passivation layer, the second back pad pattern having a width and a thickness greater than a width and a thickness of each of the plurality of first back pad patterns.

11. The semiconductor chip of claim 10, wherein the plurality of first back pad patterns are symmetrically arranged around the through via in the horizontal direction.

12. The semiconductor chip of claim 10, wherein the through via contacts an upper surface of the second back pad pattern.

13. The semiconductor chip of claim 10, wherein
an upper surface of each of the plurality of first back pad patterns is disposed higher than a lower surface of the through via.

14. The semiconductor chip of claim 10, wherein
the back pad structure includes a third back pad pattern protruding from a surface of the second back pad pattern, and
the third back pad pattern has a symmetrical structure in the horizontal direction with respect to the through via.

15. A semiconductor stack structure comprising:
a lower semiconductor chip; and
an upper semiconductor chip stacked on and bonded to the lower semiconductor chip,
wherein each of the lower semiconductor chip and the upper semiconductor chip comprises:
a body having a front surface and a back surface;
a through via extending through the front surface and the back surface;
a back insulating structure on the back surface of the body and surrounding the through via, the back insulating structure comprising a back passivation layer, a back etch stop layer and a back bonding insulating layer, sequentially disposed on the back surface; and
a back pad structure in the back insulating structure, the back pad structure comprising:
a plurality of first back pad patterns spaced apart from each other in a horizontal direction in the back passivation layer and spaced apart from the through via in the horizontal direction, and
a second back pad pattern below each of the plurality of first back pad patterns and the back passivation layer, the second back pad pattern having a width greater than a width of each of the plurality of first back pad patterns.

16. The semiconductor stack structure of claim 15, wherein
the back insulating structure of the lower semiconductor chip and the back insulating structure of the upper semiconductor chip are bonded to each other, and
the back pad structure of the lower semiconductor chip and the back pad structure of the upper semiconductor chip are bonded to each other.

17. The semiconductor stack structure of claim 15, wherein
each of the lower semiconductor chip and the upper semiconductor chip comprises:
a front insulating structure on the front surface of the body, the front insulating structure comprising a front passivation layer, a front etch stop layer and a front bonding insulating layer, sequentially disposed on the front surface; and
a front pad structure in the front insulating structure on the front surface of the body.

18. The semiconductor stack structure of claim 17, wherein
the front bonding insulating layer of the lower semiconductor chip and the front bonding insulating layer of the upper semiconductor chip are bonded to each other, and
the front pad structure of the lower semiconductor chip and the front pad structure of the upper semiconductor chip are bonded to each other.

19. The semiconductor stack structure of claim 17, wherein
the front bonding insulating layer of the lower semiconductor chip and the back bonding insulating layer of the upper semiconductor chip are bonded to each other, and
the front pad structure of the lower semiconductor chip and the back pad structure of the upper semiconductor chip are bonded to each other.

20. The semiconductor stack structure of claim 17, wherein
the back bonding insulating layer of the lower semiconductor chip and the front bonding insulating layer of the upper semiconductor chip are bonded to each other, and
the back pad structure of the lower semiconductor chip and the front pad structure of the upper semiconductor chip are bonded to each other.
